(19) United States
(12) Patent Application Publication
(10) Pub. No.: US 2020/0027491 A1
(43) Pub. Date: Jan. 23, 2020

(54) MEMORY CELL, METHODS OF FORMING AND OPERATING THE SAME

(71) Applicant: Agency for Science, Technology and Research, Singapore (SG)

(72) Inventors: Xuanyao Fong, Singapore (SG); Anh Tuan Do, Singapore (SG); Xin Liu, Singapore (SG)

(21) Appl. No.: 16/470,969

(22) PCT Filed: Dec. 18, 2017
(86) PCT No.: PCT/SG2017/050624

§ 371 Date: Jun. 18, 2019

(30) Foreign Application Priority Data
Dec. 19, 2016 (SG) 10201610608X

(51) Int. Cl. G11C 11/16; H01L 27/22; H01L 43/12; H01L 43/02

(52) U.S. Cl. CPC G11C 11/161; H01L 27/228; G11C 11/1675; H01L 43/02; H01L 43/12; G11C 11/1659; G11C 11/1673

(57) ABSTRACT

Various embodiments may provide a memory cell. The memory cell may include a magnetic tunneling junction memory including a first end and a second end. The memory cell may include a first transistor including a control electrode, a first controlled electrode and a second controlled electrode. The memory cell may also include a second transistor including a control electrode, a first controlled electrode and a second controlled electrode. The memory cell may additionally include a diode having a first end and a second end. In various embodiments, the memory cell may include a further magnetic tunneling junction memory, and a third transistor.

### CROSS-REFERENCE TO RELATED APPLICATIONS

This application claims the benefit of priority of Singapore application No. 10201610608X, filed 19 Dec. 2016, the contents of it being hereby incorporated by reference in its entirety for all purposes.

### TECHNICAL FIELD

Various embodiments relate to a memory cell. Various embodiments relate to a method of forming a memory cell. Various embodiments relate to a method of operating a memory cell.

### BACKGROUND

Computer memories are used to store temporary or permanent computer data/programs, and are typically organized in hierarchy to balance between speed/capacity trade off. Memories closer to the central processing units (CPUs) are typically faster. FIG. 1A is a schematic showing the computer memories requirement of a computer system. There is usually a trade-off between the speed and the capacity of a computer memory.

Static-random access memories (SRAMs) are the fastest and the power horse of the memory hierarchy and directly affect the performance of the system. FIG. 1B shows a memory array including several static-random access memories (SRAMs).

Current technologies for storage class memories (SCMs) face scalability issue beyond 14 nm. Magnetic random access memory (MRAM), ferroelectric random access memory (FeRAM), phase change random access memory (PCRAM), conductive bridging random access memory (CBRAM), block random access memory (BRAM), redox-based random access memory (RedoxRAM) have been proposed as alternatives to Flash memory as a storage class memory (SCM). Most of these emerging memory technologies (except FeRAM) use the resistance of the storage element to represent the stored data. FIG. 1C is a table showing the different characteristics of emerging memory technologies and conventional memories.

Several big players have such as Toshiba, Micron, Everspin etc. have been developing various emerging memories.

MRAM seems to be the most promising option due to scalability, energy efficiency and endurance.

FIG. 1D shows a schematic of a magnetic random access memory cell. FIG. 1E shows a circuit diagram of the magnetic random access memory cell. A functional magnetic random access memory cell may include a magnetic tunnel junction (MTJ) 102 and a transistor 104.

FIG. 1F shows a schematic of the magnetic tunnel junction (MTJ) 102. The MTJ supports magneto-resistive effects may include two ferromagnetic layers separated by a thin insulator layer. As the insulator layer is thin enough, electrons can tunnel through upon application of a suitable voltage. The electrons can change the magnetic orientation of the free ferromagnetic layer. FIG. 1G is a schematic illustrating the two states of a magnetic tunnel junction (MTJ). The MTJ may have a parallel state in which the magnetic orientation of the free ferromagnetic layer is parallel to the magnetic orientation of the pinned ferromagnetic layer, and an anti-parallel state in which the magnetic orientation of the free ferromagnetic layer is anti-parallel to the magnetic orientation of the pinned ferromagnetic layer.

A memory stack including several ferromagnetic layers may be formed. FIG. 1H is a plot of tunnel magnetic resistance (in percent or %) as a function of applied magnetic field (in milli Tesla or mT) showing the variation of resistances of two memory stacks. As highlighted above, the conventional spin-transfer torque magneto-resistive random access memory (STT-MRAM) memory cell has a structure including a magnetic tunnel junction structure (MTJ) and an access switch, N1. FIG. 2A shows a schematic of a conventional 1 transistor-1 magnetic tunnel junction (1T1M) memory cell. Data is stored as the resistance of the MTJ 202, which is programmed using the spin-transfer torque (STT) effect by closing the access switch 204 and passing electrical current through the MTJ 202. The direction of electrical current flow through the MTJ determines whether the final resistance of the MTJ is high or low, which is used to represent a digital bit in the memory system. In embedded memory applications, the access switch is usually an n-channel metal oxide semiconductor (NMOS) transistor.

During read operation of the conventional STT-MRAM cell, the NMOS transistor is turned on by charging its gate voltage to VDD. The bit line (BL) and source line (SL) of the bit-cell are connected to a sense amplifier to sense the resistance state of the MTJ. The basic principle behind the read operation in STT-MRAM is to compare the MTJ resistance, R_{MTJ}, with a reference resistance, R_{REF}. This may be achieved using voltage-based sensing or current-based sensing.

In voltage-based sensing, a fixed current is passed or flowed through the conventional STT-MRAM cell to generate a voltage signal. This voltage signal is compared with a reference voltage to determine the resistance of the MTJ in the conventional STT-MRAM cell. In current-based sensing, a fixed voltage is applied across the conventional STT-MRAM cell. The electrical current flowing through the memory cell is compared with a reference current to determine the resistance of the MTJ in the STT-MRAM cell.

In the current context, passing or flowing or providing a current may refer to applying a suitable voltage (e.g. using a voltage source) between a first point and a second point so that the current flows from the first point to the second point, or applying the current (e.g. using a current source).

The write operation of conventional STT-MRAM is achieved using current-induced spin-transfer torque effect. FIG. 2B show a ‘0’ being written to the memory cell shown in FIG. 2A. In order to write ‘0’, as shown in FIG. 2B, electrical current is passed from bit line (BL) to source line (SL) by applying appropriate voltages to the terminals of the conventional STT-MRAM cell. FIG. 2C show a ‘1’ being written to the memory cell shown in FIG. 2A. A 1′ is written into the cell if the electrical current flows from SL to BL instead. The switching speed of the MTJ depends on the amount of electrical current supplied during the write operation. A larger amount of electrical current results in faster switching speed.

In most embedded applications, the desired switching speed is faster than 100 MHz (switching delay less than 10 ns). The electrical current needed to achieve such switching speeds is higher than 30 A for state-of-the-art MTJs that can achieve 10 year retention times (de facto standard in the memory community). In most embedded applications, the size of the NMOS transistor needs to be enlarged in order to satisfy the memory write speed specifications.

The problem may further be exacerbated by the source degeneration issue illustrated in FIGS. 2B-C. When write current, I_{WR}, flows through the conventional STT-MRAM cell from BL to SL, the gate overdrive voltage, V_{G}S, of the NMOS transistor is VDD. When I_{WR} flows from SL to BL, the drive strength of the NMOS may be weakened due to the potential drop across the MTJ (V_{GS}=VDD V_{MTJ}, where V_{MTJ}=I_{WR}R_{MTJ}). Depending on the value of R_{MTJ} and the required I_{WR} to satisfy write speed requirements, the design of the conventional STT-MRAM cell may be limited by the source degeneration issue.

### SUMMARY

Various embodiments may provide a memory cell. The memory cell may include a magnetic tunneling junction memory including a first end and a second end. The memory cell may include a first transistor including a control electrode, a first controlled electrode and a second controlled electrode. The memory cell may also include a second transistor including a control electrode, a first controlled electrode and a second controlled electrode. The memory cell may additionally include a diode having a first end and a second end.

The second controlled electrode of the first transistor may be coupled to the first end of the magnetic tunneling junction memory. The second end of the magnetic tunneling junction memory may be coupled to the first controlled electrode of the second transistor and the first end of the diode. The control electrode of the first transistor may be configured to be coupled to a word line. The first controlled electrode of the first transistor may be configured to be coupled to a bit line. The control electrode of the second transistor may be configured to be coupled to an input. The second controlled electrode of the second transistor may be configured to be coupled to a first source line. The second end of the diode may be configured to be coupled to a second source line.

Various embodiments may provide a method of forming a memory cell. The method may include providing a magnetic tunneling junction memory including a first end and a second end. The method may also include providing a first transistor including a control electrode, a first controlled electrode and a second controlled electrode. The method may further include providing a second transistor including a control electrode, a first controlled electrode and a second controlled electrode. The method may additionally include providing a diode having a first end and a second end.

The method may further include coupling the second controlled electrode of the first transistor to the first end of the magnetic tunneling junction memory. The method may also include coupling the second end of the magnetic tunneling junction memory to the first controlled electrode of the second transistor and the first end of the diode. The method may additionally include coupling the control electrode of the first transistor to a word line. The method may also include coupling the first controlled electrode of the first transistor to a bit line. The method may further include coupling the control electrode of the second transistor to an input. The method may additionally include coupling the second controlled electrode of the second transistor to a first source line. The method may also include coupling the second end of the diode to a second source line.

Various embodiments may provide a method of operating a memory cell according to various embodiments. The method may include providing said memory cell. The memory cell may include a magnetic tunneling junction memory including a first end and a second end. The memory cell may also include a first transistor including a control electrode, a first controlled electrode and a second controlled electrode. The memory cell may further include a second transistor including a control electrode, a first controlled electrode and a second controlled electrode. The memory cell may additionally include a diode having a first end and a second end.

The method may also include flowing or passing a first write current through the magnetic tunneling junction in a first direction to write a first logic state in the magnetic junction memory. The method may additionally include flowing or passing a second write current through the magnetic tunneling junction in a second direction opposite the first direction to write a second logic state in the magnetic junction memory.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A is a schematic showing the computer memories requirement pf a computer system.

FIG. 1B shows a memory array including several static-random access memories (SRAMs).

FIG. 1C is a table showing the different characteristics of emerging memory technologies and conventional memories.

FIG. 1D shows a schematic of a magnetic random access memory cell.

FIG. 1E shows a circuit diagram of the magnetic random access memory cell.

FIG. 1F shows a schematic of the magnetic tunnel junction (MTJ).

FIG. 1G is a schematic illustrating the two states of a magnetic tunnel junction (MTJ).

FIG. 1H is a plot of tunnel magnetic resistance (in percent or %) as a function of applied magnetic field (in milli Tesla or mT) showing the variation of resistances of the two memory stacks.

FIG. 2A shows a schematic of a conventional 1 transistor-1 magnetic tunnel junction (1T1M) memory cell.

FIG. 2B show a ‘0’ being written to the memory cell shown in FIG. 2A.

FIG. 2C show a ‘1’ being written to the memory cell shown in FIG. 2A.

FIG. 3A shows a conventional 1 transistor-1 magnetic tunnel junction (1T1M) memory cell schematic during read operation.

FIG. 3B shows a 2 transistors-1 magnetic tunnel junction (1TG1M) memory cell schematic during read operation.

FIG. 3C shows another 2 transistors-1 magnetic tunnel junction (2T1M) memory cell schematic during read operation.

FIG. 3D shows yet another 2 transistors-1 magnetic tunnel junction (2T1M) memory cell schematic.

FIG. 3E shows a 2 transistors-2 magnetic tunnel junctions (2T2M) memory cell schematic.

FIG. 3F shows another 4 transistors-2 magnetic tunnel junctions (2T2M) memory cell schematic.

FIG. 3G shows a cross-sectional schematic of a 1 transistor-1 magnetic tunnel junction (1 T1M) memory cell.

FIG. 4 is a general illustration of a memory cell according to various embodiments.

FIG. 5A shows a schematic of a memory cell according to various embodiments.

FIG. 5B shows a schematic of the memory cell shown in FIG. 5A when reading or writing a first logic state according to various embodiments.

FIG. 5C shows a schematic of the memory cell shown in FIG. 5A when writing a second logic state according to various embodiments.

FIG. 5D is a table showing the control voltages that may be applied to the memory cell shown in FIG. 5A according to various embodiments.

FIG. 6A shows a schematic of a memory cell according to various embodiments.

FIG. 6B shows a schematic of the memory cell shown in FIG. 6A in high density mode when writing a first logic state to the magnetic tunneling junction memory according to various embodiments.

FIG. 6C shows a schematic of the memory cell shown in FIG. 6A in high density mode when writing a second logic state when writing a first logic state to the magnetic tunneling junction memory according to various embodiments.

FIG. 6D shows a schematic of the memory cell shown in FIG. 6A in high density mode when reading a logic state of the magnetic tunneling junction memory according to various embodiments.

FIG. 6E shows a schematic of the memory cell shown in FIG. 6A in high density mode when reading a logic state of the further magnetic tunneling junction memory according to various embodiments.

FIG. 6F is a table showing the control voltages for reading and writing the first magnetic memory junction of the memory cell shown in FIG. 6A in high density mode according to various embodiments.

FIG. 6G shows a schematic of the memory cell shown in FIG. 6A in differential mode during a read operation according to various embodiments.

FIG. 6H shows a schematic of the memory cell shown in FIG. 6A in differential mode during a clear operation according to various embodiments.

FIG. 6I shows a schematic of the memory cell shown in FIG. 6A during a differential write operation to write a first logic state to the memory cell according to various embodiments.

FIG. 6J shows a schematic of the memory cell shown in FIG. 6A during another differential write operation to write a second logic state to the memory cell according to various embodiments.

FIG. 6K is a table showing the control voltages for read and clear operations of the memory cell shown in FIG. 6A in differential mode according to various embodiments.

FIG. 6L is a table showing the control voltages for writing to the memory cell as shown in FIGS. 6I-J according to various embodiments.

FIG. 7A compares the memory cells shown in FIG. 5A (Proposed 1) and FIG. 6A (Proposed 2) with a 1-transistor-1-magnetic tunneling junction (1T1M) cell architecture and a 1-transmission gate-1-magnetic tunneling junction (1TG1M) cell architecture during a read operation.

FIG. 7B compares the memory cells shown in FIG. 5A (Proposed 1) with a 1-transistor-1-magnetic tunneling junction (1T1M) cell architecture and a 1-transmission gate (TG)-1-magnetic tunneling junction (1 TG1M) cell architecture during a write operation. The cell may store data based on the resistance of the MTJ.

FIG. 7C compares the memory cells shown in FIG. 5A (Proposed 1) and FIG. 6A (Proposed 2) during write operations and a clean/reset operation.

FIG. 7D is a schematic illustrating the AWARE-cache method which may be employed by a memory array according to various embodiments.

FIG. 7E is another schematic illustrating the AWARE-cache method which may be employed by a memory array according to various embodiments.

FIG. 7F illustrates a conventional cache operation.

FIG. 7G illustrates an array operation for a 3-transistors-1-magnetic tunneling junction (3T1MTJ) cell or a 4-transistors-2-magnetic tunneling junctions (4T2MTJ) cell.

FIG. 8A shows (above) a plot of voltage as a function of time applied to the control terminals of the memory cell shown in FIG. 5A to show sequential write and hold operations according to various embodiments, and (below) a plot of resistance (in kilo-ohms or kΩ) as a function of time showing the resistance state of the memory cell shown in FIG. 5A according to various embodiments.

FIG. 8B is a plot of current as a function of time showing the currents supplied by the voltage source driving the bitline as well as the current flowing through the magnetic tunneling junction of the memory cell shown in FIG. 5A according to various embodiments.

FIG. 9A shows (top) a plot of voltage as a function of time illustrating the voltage applied to the word line (WL_{A}) of the memory cell shown in FIG. 6A for sequential write and hold operations; (middle) a plot of voltage as a function of time illustrating the voltage applied to the bit line (BL_{A}) and the first source line (SL_{A}) of the memory cell shown in FIG. 6A for sequential write and hold operations; and (bottom) a plot of voltage as a function of time illustrating the voltage applied to the second source line (SL_{B}) and the input (ACT) of the memory cell shown in FIG. 6A for sequential write and hold operations.

FIG. 9B shows a plot of resistance (in ohms or Ω) as a function of time showing the resistance state of the memory cell shown in FIG. 6A according to various embodiments.

FIG. 10 shows a schematic of a method of forming a memory cell according to various embodiments.

FIG. 11 shows a schematic of a method of operating a memory cell according to various embodiments.

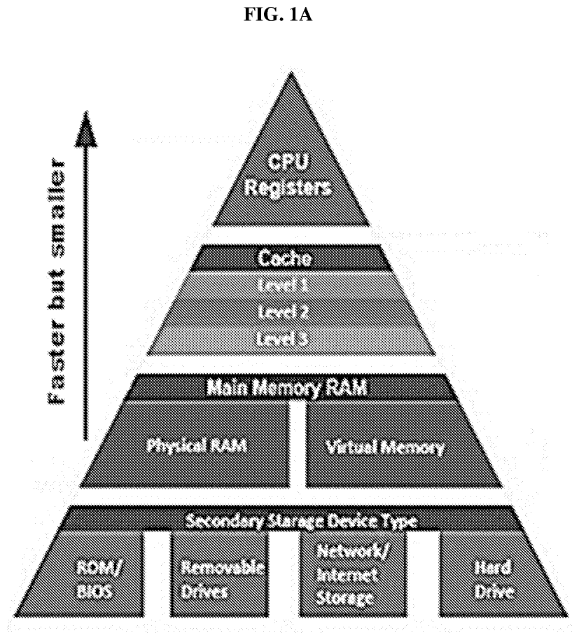

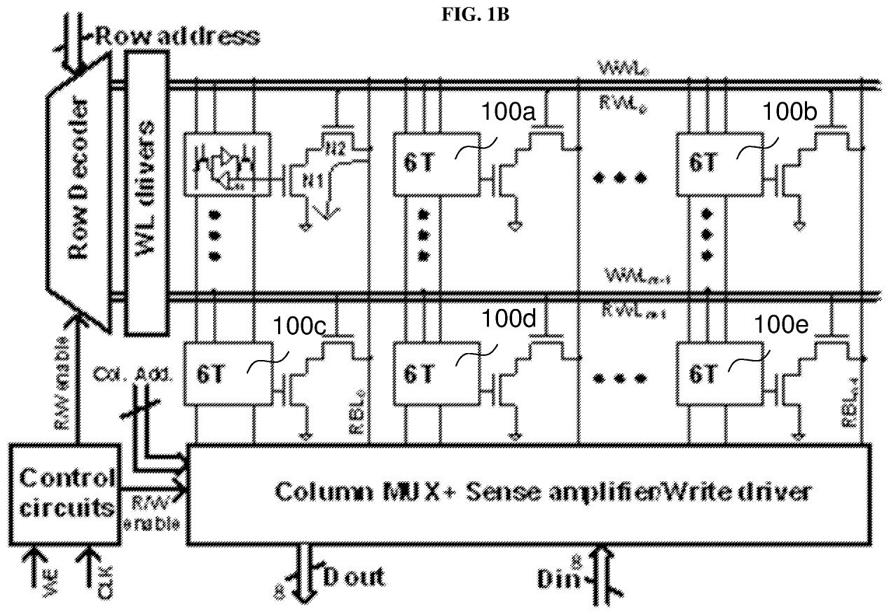

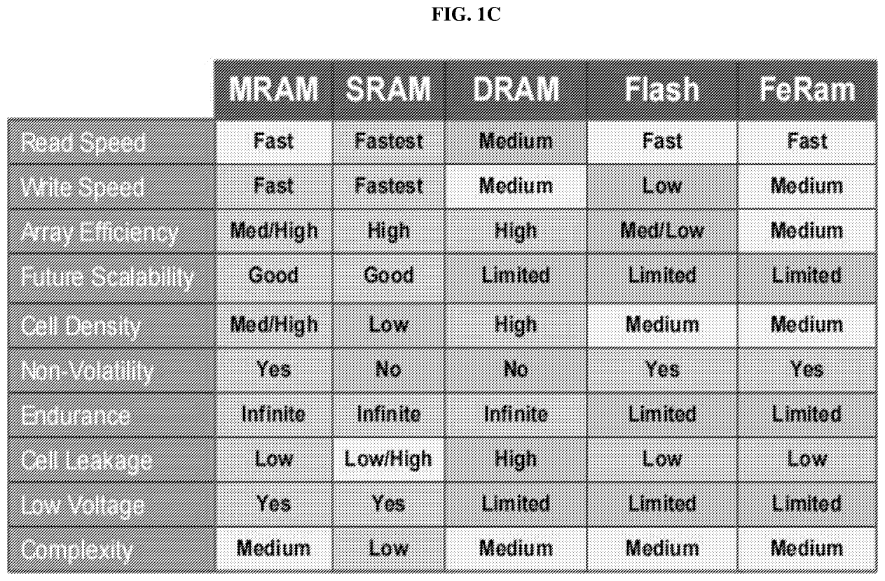

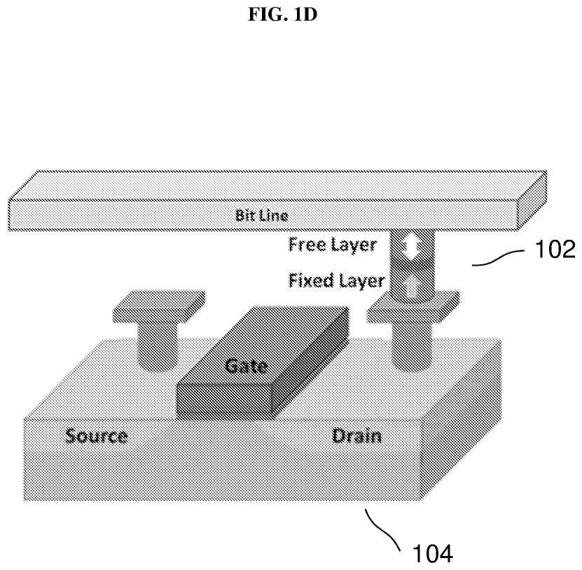

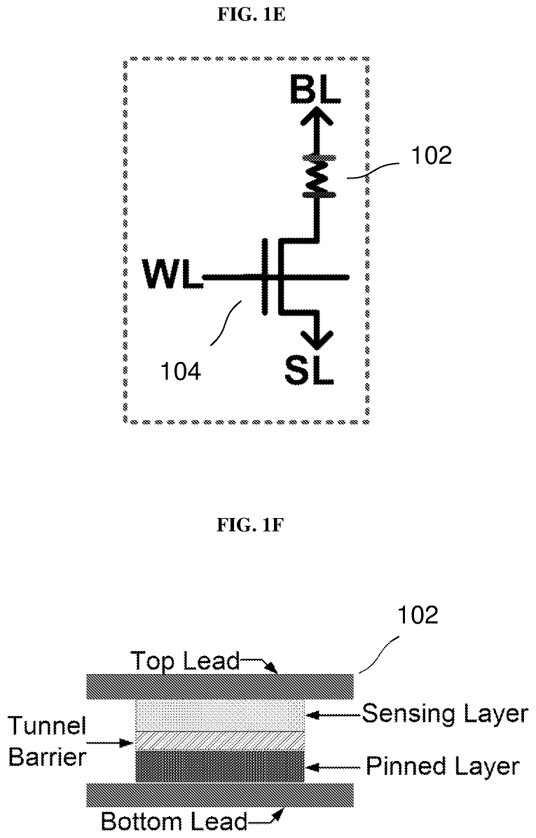

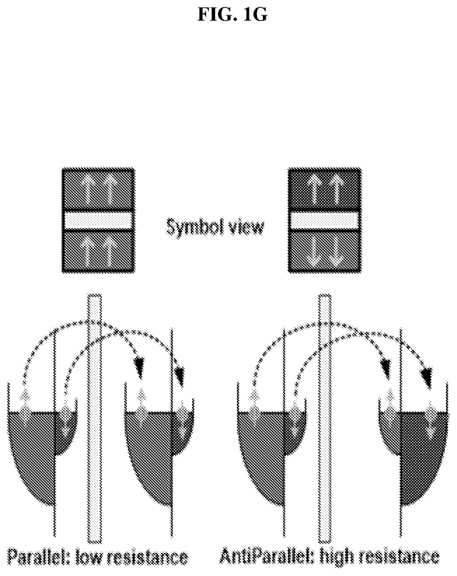

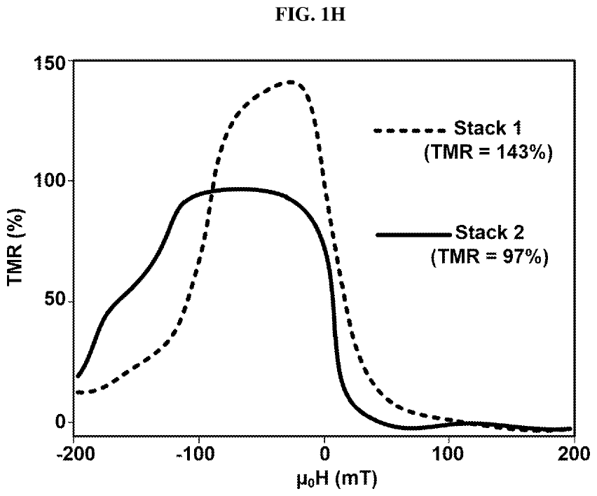

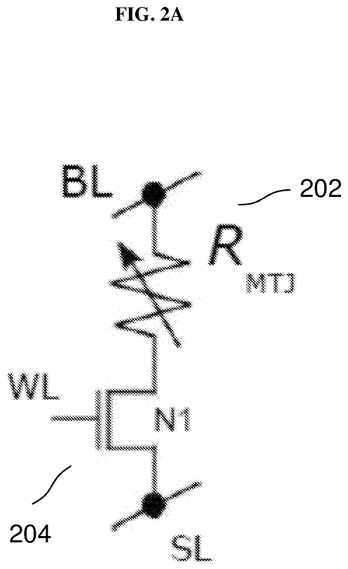

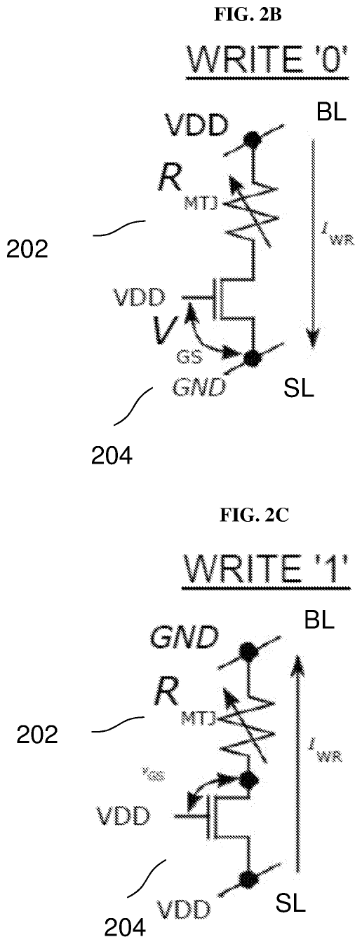

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or memory cells are analogously valid for the other methods or memory cells. Similarly, embodiments described in the context of a method are analogously valid for a memory cell, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may address or mitigate the source degeneration issue facing the conventional spin transfer torque-magnetic random access memory (STT-MRAM cell). Various embodiments may have other advantages over the conventional 1 transistor-1 MTJ (1T1M) design or other cell designs. Various embodiments may be a spin transfer torque-magnetic random access memory (STT-MRAM) memory cell.

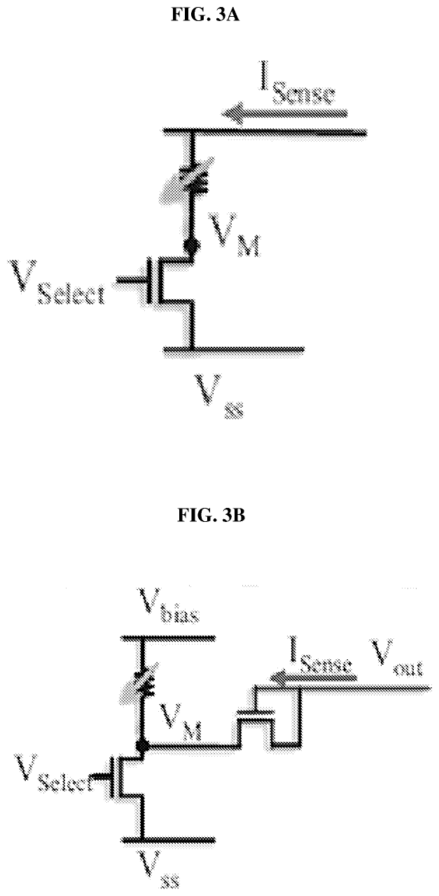

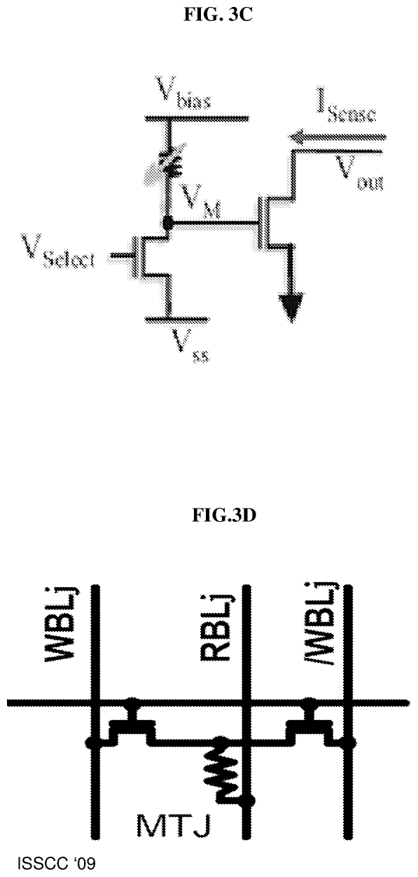

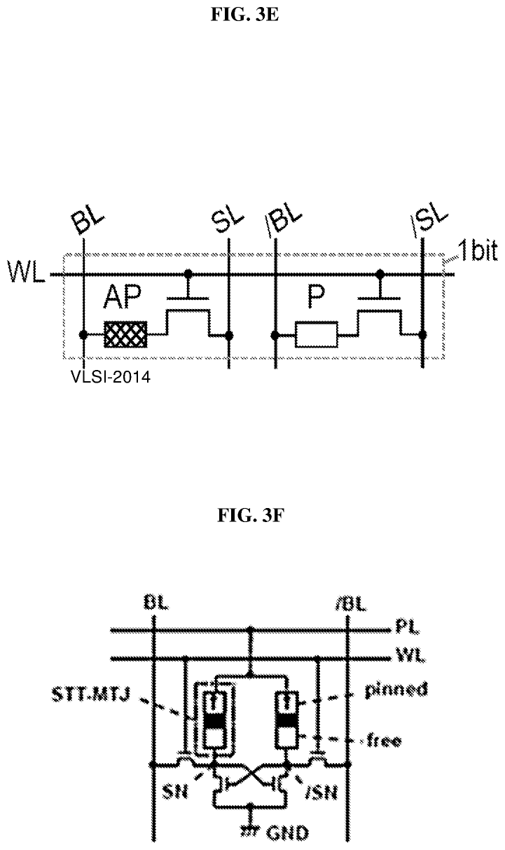

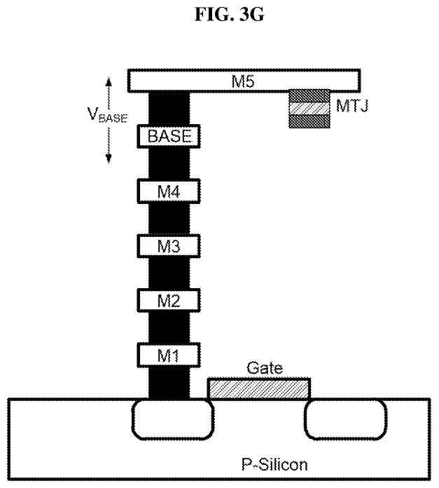

FIG. 3A shows a conventional 1 transistor-1 magnetic tunnel junction (1T1M) memory cell schematic during read operation. FIG. 3B shows a 2 transistors-1 magnetic tunnel junction (1TG1M) memory cell schematic during read operation. FIG. 3C shows another 2 transistors-1 magnetic tunnel junction (2T1M) memory cell layout during read operation. FIG. 3D shows yet another 2 transistors-1 magnetic tunnel junction (2T1M) memory cell layout.

FIG. 3E shows a 2 transistors-2 magnetic tunnel junctions (2T2M) memory cell layout. FIG. 3F shows another 4 transistors-2 magnetic tunnel junctions (2T2M) memory cell schematic. FIG. 3G shows a cross-sectional schematic of a 1 transistor-1 magnetic tunnel junction (1T1M) memory cell. A magnetic tunnel junction (MTJ) may also be referred to as a magnetic tunneling junction memory. The magnetic tunnel junction may include a free ferromagnetic layer and a pinned ferromagnetic layer, as well as an insulating layer (including a material such as magnesium oxide) separating the free ferromagnetic layer and the pinned ferromagnetic layer. The pinned ferromagnetic layer may have a direction of magnetization that is invariant, i.e. does not change, in response to a current, e.g. a writing current, as described herein. In contrast, the free ferromagnetic layer may have a direction of magnetization that changes in response to a current, e.g. a writing current, as described herein.

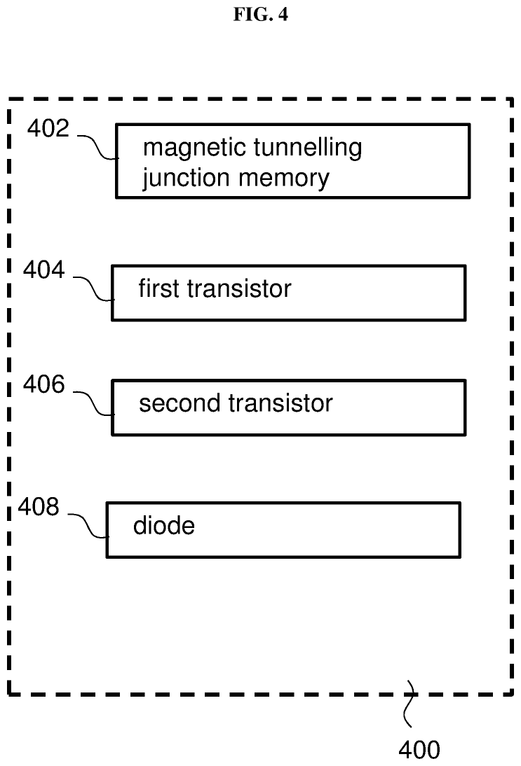

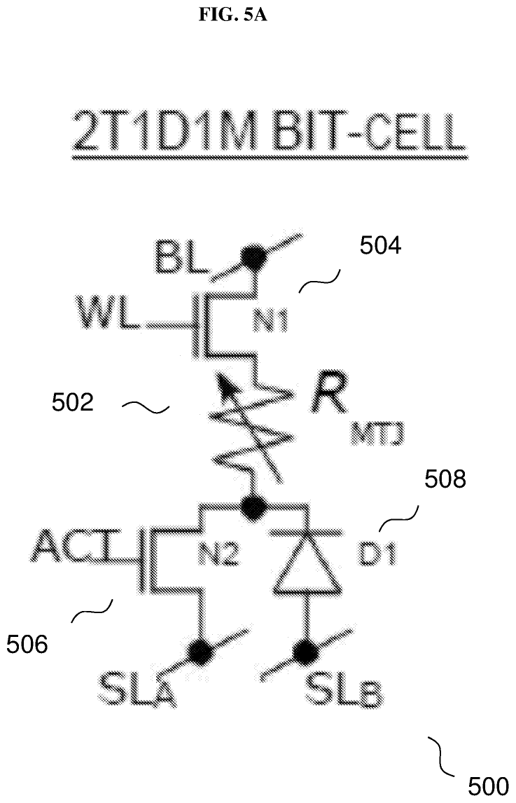

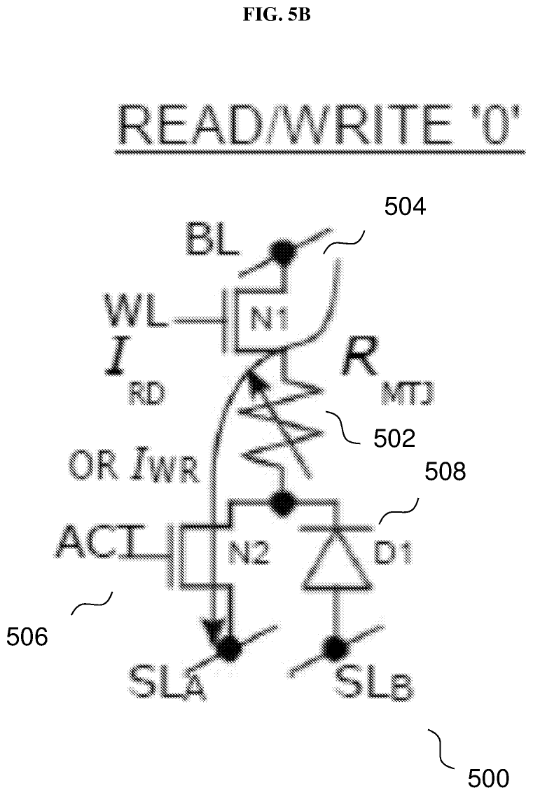

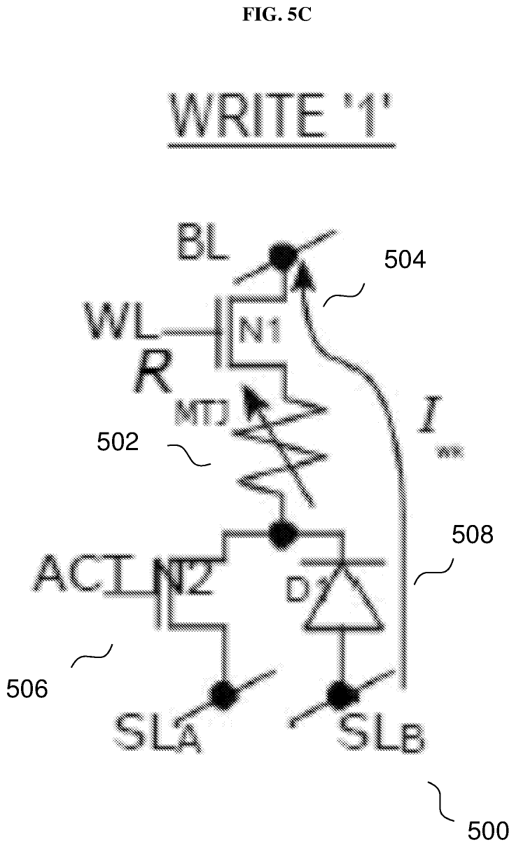

FIG. 4 is a general illustration of a memory cell 400 according to various embodiments. The memory cell 400 may include a magnetic tunneling junction memory 402 including a first end and a second end. The memory cell 400 may include a first transistor 404 including a control electrode, a first controlled electrode and a second controlled electrode. The memory cell 400 may also include a second transistor 406 including a control electrode, a first controlled electrode and a second controlled electrode. The memory cell 400 may additionally include a diode 408 having a first end and a second end.

The second controlled electrode of the first transistor 404 may be coupled to the first end of the magnetic tunneling junction memory 402. The second end of the magnetic tunneling junction memory 402 may be coupled to the first controlled electrode of the second transistor 406 and the first end of the diode. The control electrode of the first transistor 404 may be configured to be coupled to a word line. The first controlled electrode of the first transistor 404 may be configured to be coupled to a bit line. The control electrode of the second transistor 406 may be configured to be coupled to an input. The second controlled electrode of the second transistor 406 may be configured to be coupled to a first source line. The second end of the diode 408 may be configured to be coupled to a second source line.

In the current context, a transistor may be turned or switched on (alternatively referred to as “activated”) when a substantial current, i.e. a current higher than the sub-threshold current, flows between the first controlled electrode and the second controlled electrode. Conversely, a transistor may be turned or switched off (alternatively referred to as “deactivated”) when no current or an insubstantial current, i.e. the sub-threshold current, flows between the first controlled electrode and the second controlled electrode.

The sub-threshold current may, for instance, be of any value lower than 10⁻⁶ A or 10⁻⁷ A.

In the current context, a first electrical element coupled to a second electrical element may refer to the first electrical element electrically connected to the second electrical element. In various embodiments, a first electrical element coupled to a second electrical element may refer to the first electrical element joined to the second electrical element either directly or via one or more electrically conductive lines.

In various embodiments, a control electrode of a transistor may refer to a gate electrode of the transistor. In various embodiments, the first controlled electrode of a transistor may refer to a source electrode of the transistor and the second controlled electrode of the transistor may refer to a drain electrode of the transistor, while in various other embodiments, the first controlled electrode of a transistor may refer to a drain electrode of the transistor and the second controlled electrode of the transistor may refer to a source electrode of the transistor. In various embodiments, the first end of the magnetic tunneling junction memory may refer to a top electrode of the magnetic tunneling junction memory, and the second end of the magnetic tunneling junction memory may refer to a bottom electrode of the magnetic tunneling junction memory.

In various embodiments, a transistor as described herein may be a n-channel metal oxide semiconductor (NMOS) transistor, while in various other embodiments, the transistor may be a p-channel metal oxide semiconductor (PMOS) transistor.

In various embodiments, a reference to a line or input, such as a word line, may also include a reference to a terminal of the word line, vice versa.

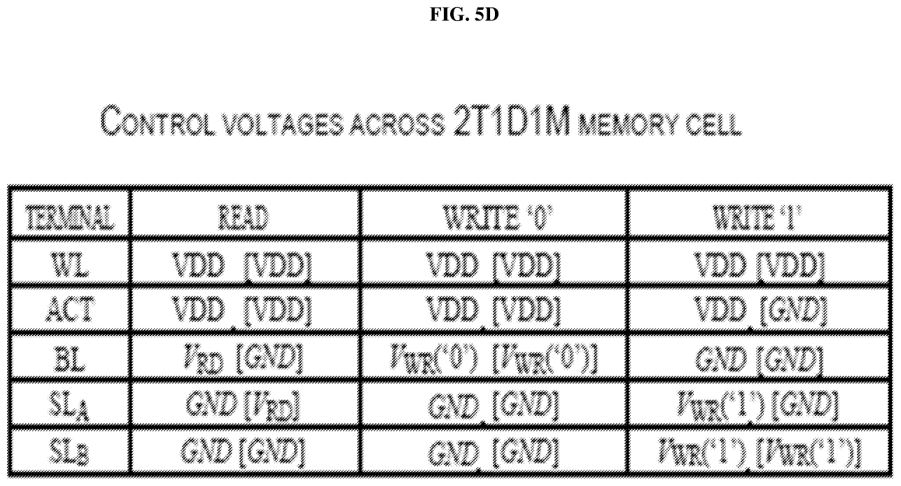

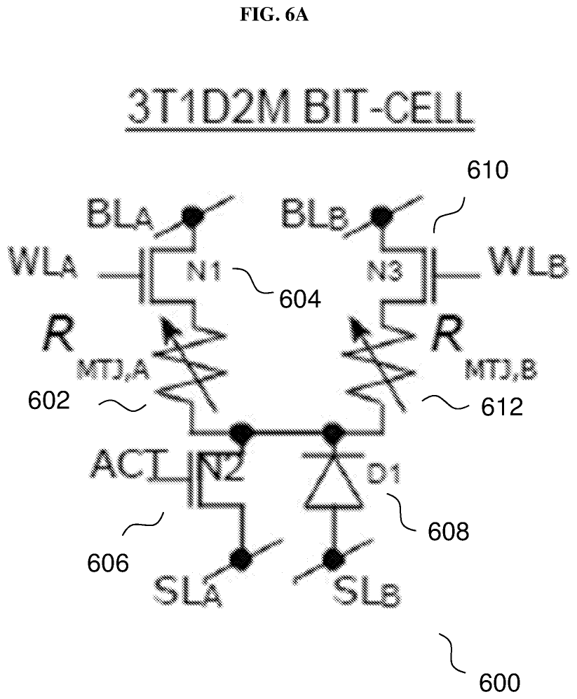

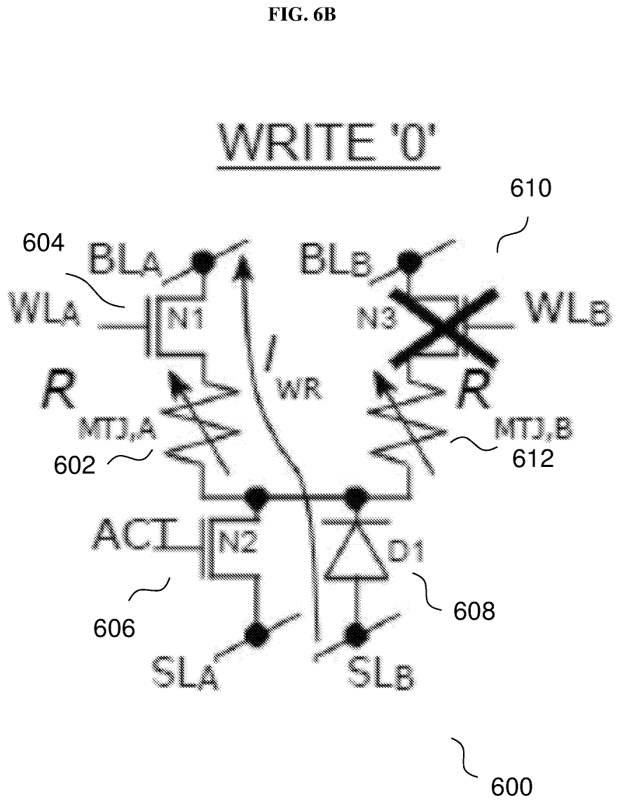

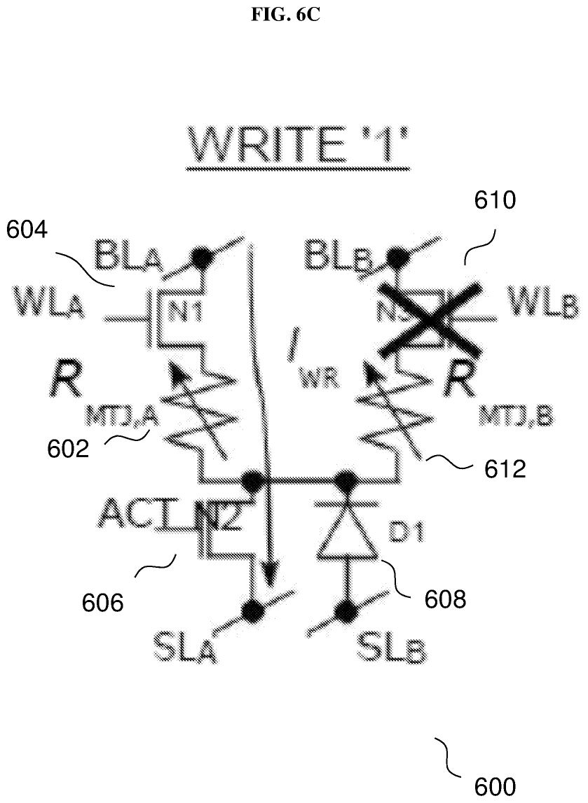

FIG. 5A shows a schematic of a memory cell 500 according to various embodiments. FIG. 5B shows a schematic of the memory cell 500 shown in FIG. 5A when reading or writing a first logic state according to various embodiments. FIG. 5C shows a schematic of the memory cell 500 shown in FIG. 5A when writing a second logic state according to various embodiments.

The memory cell 500 may include a magnetic tunneling junction memory 502 including a first end and a second end. The memory cell 500 may include a first transistor 504 (N₁) including a control electrode, a first controlled electrode and a second controlled electrode. The memory cell 500 may also include a second transistor 506 (N₂) including a control electrode, a first controlled electrode and a second controlled electrode. The memory cell 500 may additionally include a diode 508 (D₁) having a first end and a second end.

The second controlled electrode of the first transistor 504 may be coupled to the first end of the magnetic tunneling junction memory 502. The second end of the magnetic tunneling junction memory 502 may be coupled to the first controlled electrode of the second transistor 506 and the first end of the diode 508. The control electrode of the first transistor 504 may be configured to be coupled to a word line (WL). The first controlled electrode of the first transistor 504 may be configured to be coupled to a bit line (BL). The control electrode of the second transistor 506 may be configured to be coupled to an input (ACT). The second controlled electrode of the second transistor 506 may be configured to be coupled to a first source line (SL_{A}). The second end of the diode 508 may be configured to be coupled to a second source line (SL_{B}).

In other words, the first transistor 504 may be connected to one end of the magnetic tunneling junction memory 502, while the second transistor 506 and the diode 508 may be connected to another end of the magnetic tunneling junction memory 502.

The memory cell 500 may be referred to as a 2-transistors-1-diode-1-MTJ memory cell, i.e. a 2T1D1M cell.

The diode 508 may be so arranged or coupled that the diode 508 allows a substantial current to flow in a direction towards the magnetic tunneling junction memory 502, but prevents a substantial current from flowing in a direction away from the magnetic tunneling junction memory 502. The diode 508 may be configured to allow only a substantial current to flow from the second end of the diode 508 to the first end of the diode 508, and may be configured to prevent a substantial current from flowing from the first end of the diode 508 to the second end of the diode 508.

The first transistor 504 may be configured to be switched on by the word line WL and the second transistor 506 may be configured to be switched on by the input ACT so that a first write current flows from the bit line BL through the first transistor 504 and the second transistor 506 to the first source line SL_{A} to write a first logic state in the magnetic tunneling junction memory 502.

The first transistor 504 may be configured to be switched on by the word line WL so that a second write current flows from the second source line (SL_{B}) through the diode 508 and the first transistor 502 to the bit line BL to write a second logic state in the magnetic tunneling junction memory 502. In various embodiments, the second transistor 506 may be configured to be switched on by the input ACT so that a supplementary write current flows from the first source line SL_{A} through the second transistor 506 and the first transistor 504 to the bit line BL to write the second logic state in the magnetic tunneling junction memory 502. In other words, the current flow through the magnetic tunneling junction memory 502 may be from both SL_{A} and SL_{B}.

In various other embodiments, the second transistor 506 may be configured to be switched off.

The first transistor 504 may be configured to be switched on by the word line WL and the second transistor 506 may be configured to be switched on by the input ACT so that a read current flows from the bit line BL through the first transistor 504 and the second transistor 506 to the first source line SL_{A} to determine a logic state in the magnetic tunneling junction memory 502.

The first transistor 504 may be a n-channel metal oxide semiconductor (NMOS) transistor. The first transistor 504 may act as an access switch controlled by the voltage on the word line (WL) terminal.

The second transistor 506 may be a n-channel metal oxide semiconductor (NMOS) transistor. The second transistor 506 may act as a read switch controlled by the voltage on the ACT terminal.

When activated or turned on, the first transistor 504 may connect the BL terminal of the 2T1D1M memory cell structure 500 to one terminal of the MTJ. The remaining terminal of the MTJ 502 may be connected to one terminal of the diode 508, D1. The same terminal of the diode 508 may be connected to one terminal of the second transistor 506. The second terminal of the diode 508 may be connected to the SL_{B} terminal of the 2T1D1M memory cell structure 500. When activated or tuned on, the second transistor 506 may connect the SL_{A} terminal of the 2T1D1M memory cell structure 500 to the terminal of diode 508 that is connected to the MTJ 502.

When the 2T1D1M memory cell 500 is selected for writing, the voltage of the WL terminal may be set to turn the access switch, i.e. first transistor 504, on. When a first logic state, e.g. a ‘0’, is to be written, the voltage of the ACT terminal may be set to turn the read switch, i.e. second transistor 506, on. The voltages on the BL and SL_{A} terminals may also be set so that an electrical current, i.e. the first write current, flows from the BL terminal to the SL_{A} terminal through the MTJ 502. The voltage on the BL terminal may be set to be higher than the voltage on the SL_{A} terminal. For instance, the voltage on the BL terminal may be set to VDD and the voltage on the SL_{A} terminal may be set to ground.

If instead a second logic state, e.g. a ‘1’, is to be written, the voltages on the BL and SL_{B} terminals may be set so that an electrical current, i.e. the second write current, flows from the SL_{B} terminal to the BL terminal through the MTJ 502.

In various embodiments, a supplementary write current may flow from the SL_{A} terminal through the second transistor 506, the MTJ 502 and the first transistor 502 to the BL terminal during writing of the second logic state. The current flow through the MTJ 502 when writing ‘1’ may come from the second write current from SL_{B} and the supplementary write current from SL_{A}. More write current may be supplied to the MTJ 502 during writing of the second logic state by setting the voltages on the ACT and SL_{A} terminals so that electrical current flowing through the MTJ 502 comes from both the diode 508 and the read switch 506. Various embodiments may thus mitigate or address the source degeneration issue face by conventional memory cells.

During the read operation, the voltage at the WL terminal of the 2T1D1M memory cell 500 may turn on access switch 502 and the voltage at the ACT terminal may turn on read switch 506. If a current-based sensing scheme is used, the voltages of BL and SL_{A} may be set (at fixed values) so that the current flowing through the MTJ is I_{RD}. I_{RD} may then be compared with a reference current to determine the state of the MTJ in the 2T1D1M memory cell. If a voltage-based sensing scheme is used, a fixed electrical current, I_{RD}, may be passed between BL and SL_{A}. Negligible current may flow through the diode 508 during read operations. The voltage developed between the BL terminal and the SL_{A} terminal may be compared to a reference voltage to determine the state of the MTJ in the 2T1D1M memory cell.

FIG. 5D is a table showing the control voltages that may be applied to the memory cell 500 shown in FIG. 5A according to various embodiments. The voltages in brackets denote the alternative set of voltages which may be applied to the respective terminals. For instance, during a read operation, BL may be set to V_{RD} and SL_{A} may be set to GND (i.e. ground or 0V) in various embodiments, while BL may be set to GND and SL_{A} may be set to V_{RD} in various other embodiments. During writing a ‘1’, ACT may be set to VDD and SL_{A} may be set to V_{WR} according to various embodiments, while ACT and SL_{A} may be both set to GND in various other embodiments.

VDD may be of any suitable value. In various embodiments, VDD may be any suitable value selected from a range of 0.5 V to 1.5 V. V_{WR} may be of any suitable value. In various embodiments, V_{WR} may be any suitable value selected from a range of 0.5 V to 1.5 V. V_{RD} may be of any suitable value. In various embodiments, V_{RD} may be any suitable value selected from a range of 0.5 V to 1.5 V.

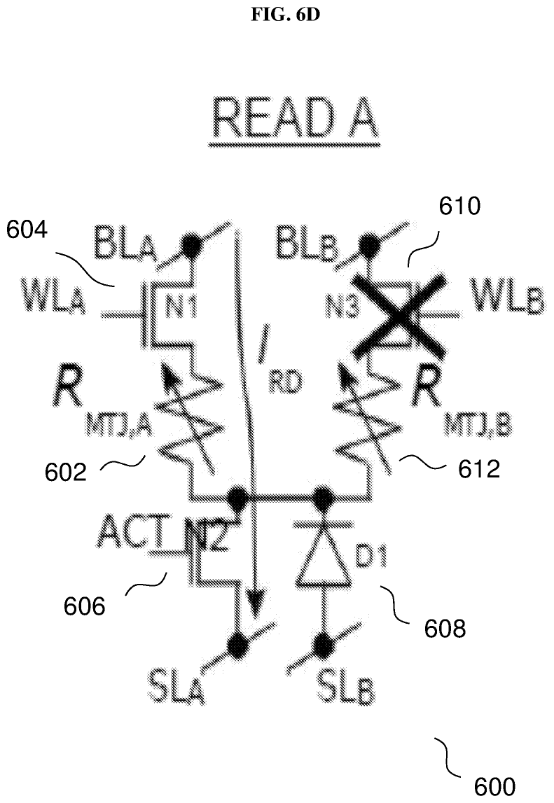

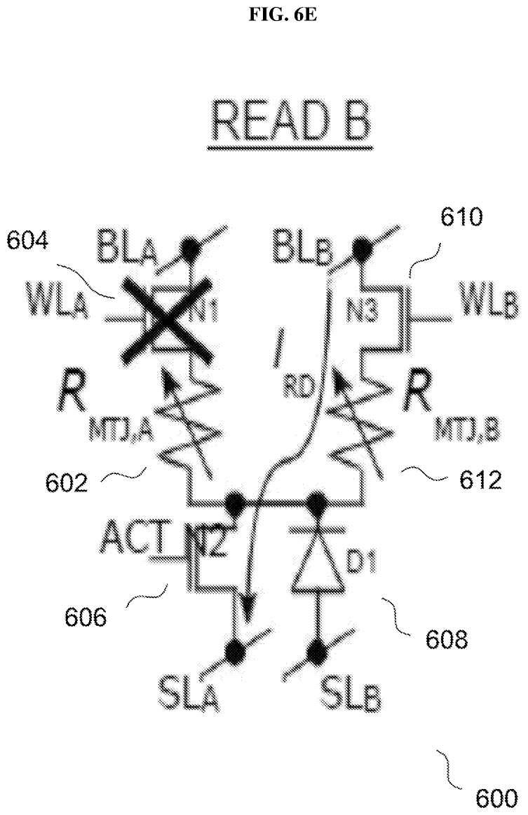

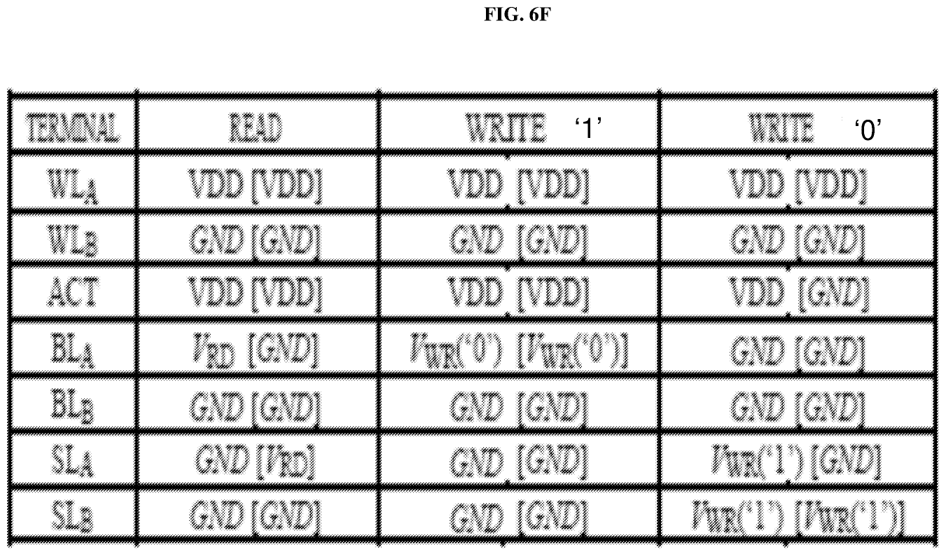

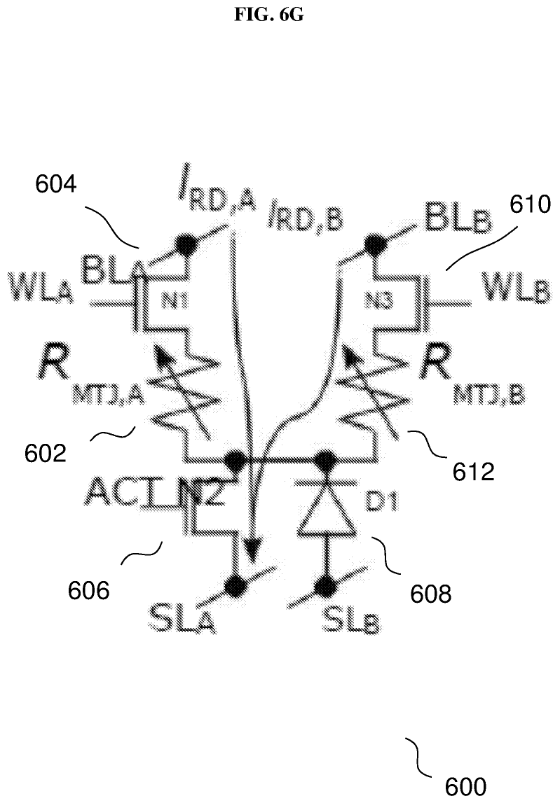

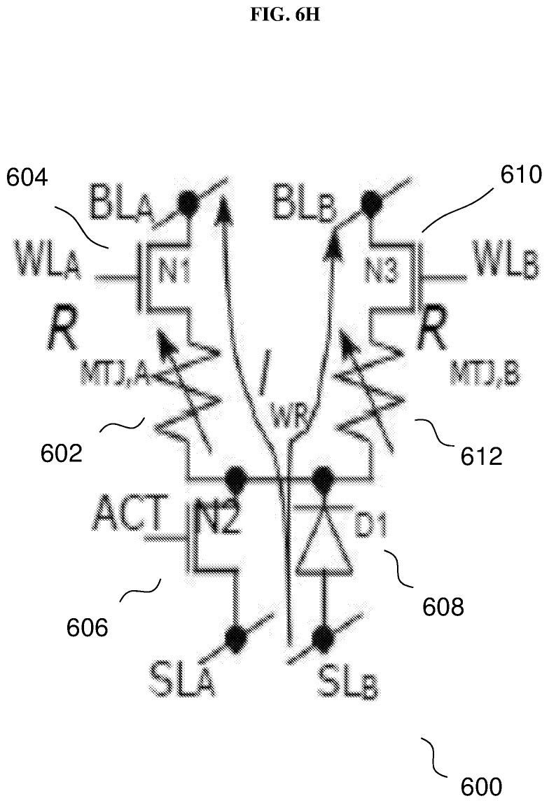

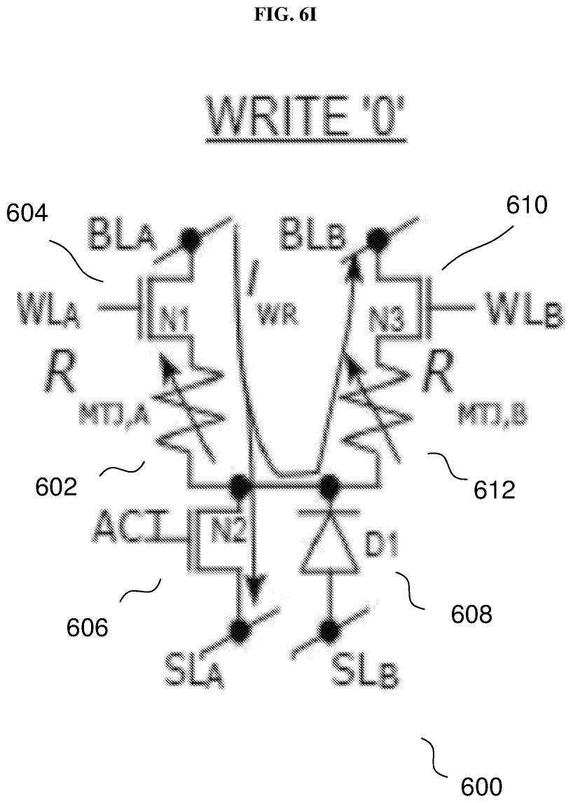

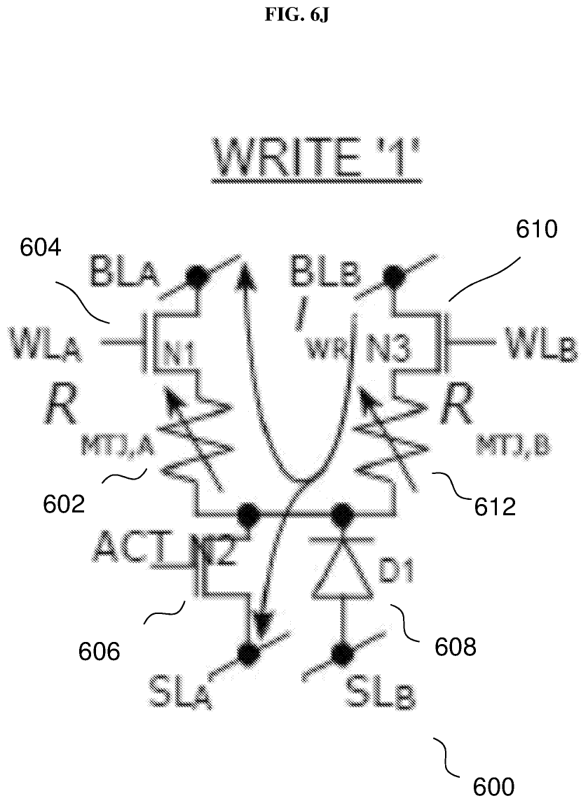

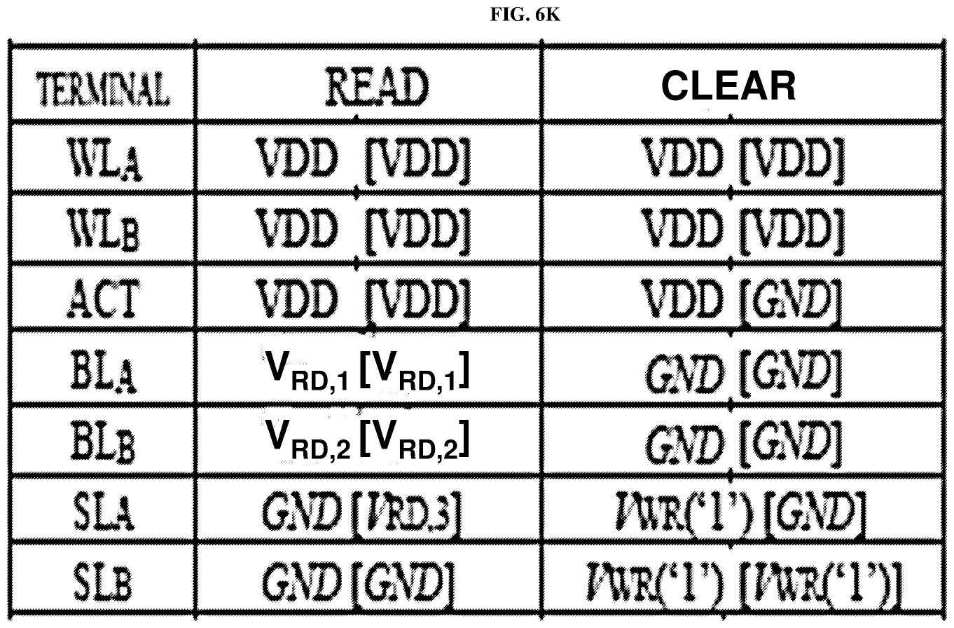

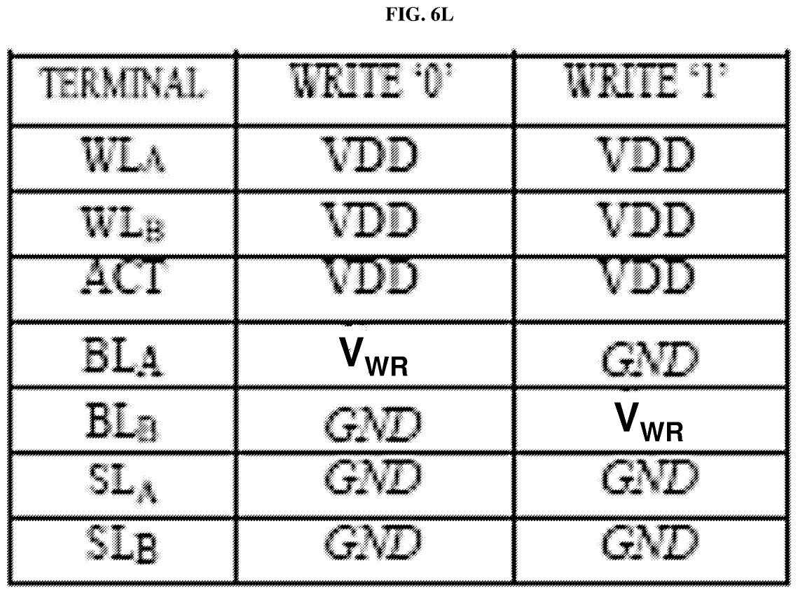

FIG. 6A shows a schematic of a memory cell 600 according to various embodiments. The memory cell 600 may be referred to as a 3-transistors-1-diode-2-MTJs (3T1D2M) memory cell.

The memory cell 600 may include a magnetic tunneling junction memory 602 including a first end and a second end. The memory cell 600 may include a first transistor 604 (N₁) including a control electrode, a first controlled electrode and a second controlled electrode. The memory cell 600 may also include a second transistor 606 (N₂) including a control electrode, a first controlled electrode and a second controlled electrode. The memory cell 600 may additionally include a diode 608 (D₁) having a first end and a second end.

The second controlled electrode of the first transistor 604 may be coupled to the first end of the magnetic tunneling junction memory 602. The second end of the magnetic tunneling junction memory 602 may be coupled to the first controlled electrode of the second transistor 606 and the first end of the diode 608. The control electrode of the first transistor 604 may be configured to be coupled to a word line (WL_{A}). The first controlled electrode of the first transistor 604 may be configured to be coupled to a bit line (BL_{A}). The control electrode of the second transistor 606 may be configured to be coupled to an input (ACT). The second controlled electrode of the second transistor 606 may be configured to be coupled to a first source line (SL_{A}). The second end of the diode 608 may be configured to be coupled to a second source line (SL_{B}).

The memory cell 600 may further include a third transistor 610 including a control electrode, a first controlled electrode and a second controlled electrode. The memory cell 600 may also include a further magnetic tunneling junction memory 612 including a first end and a second end.

The second end of the further magnetic tunneling junction memory 612 may be coupled to the second end of the magnetic tunneling junction memory 602. The second end of the further magnetic tunneling junction memory 612 may be coupled to the first end of the diode 608 as well as the first controlled electrode of the second transistor 606.

The control electrode of the third transistor 610 may be configured to be coupled to a further word line (WL_{B}). The first controlled electrode of the third transistor 610 may be configured to be coupled to a further bit line (BL_{B}).

In other words, the memory cell 600 may include two magnetic tunneling junction memories 602, 612. The two magnetic tunneling junction memories 602, 612 may be coupled together. The common node of the two magnetic tunneling junction memories 602, 612 may also be joined to the diode 608 and the second transistor 606. The other end of the magnetic tunneling junction memory 602 may be joined to the first transistor 604, while the other end of the further tunneling junction memory 602 may be joined to the third transistor 610.

The diode 608 may be so arranged or coupled that the diode 608 allows a substantial current to flow in a direction towards the magnetic tunneling junction memory 602 or further magnetic tunneling junction memory 612, but prevents a substantial current from flowing in a direction away from the magnetic tunneling junction memory 602 or further magnetic tunneling junction memory 612. The diode 608 may be configured to allow only a substantial current to flow from the second end of the diode 608 to the first end of the diode 608, and may be configured to prevent a substantial current from flowing from the first end of the diode 608 to the second end of the diode 608.

The memory cell 600 may be configured to be operated in high density mode or in differential mode.

FIG. 6B shows a schematic of the memory cell 600 shown in FIG. 6A in high density mode when writing a first logic state to the magnetic tunneling junction memory 602 according to various embodiments. FIG. 6C shows a schematic of the memory cell 600 shown in FIG. 6A in high density mode when writing a second logic state when writing a first logic state to the magnetic tunneling junction memory 602 according to various embodiments.

In various embodiments, the magnetic tunneling junction memory 602 may be configured to store a first bit of data and the further magnetic tunneling junction memory 612 may be configured to store a second bit of data. The operation mode shown in FIGS. 6B and 6C may be known as high density mode. In the high density mode, each MTJ 602, 612 may store a bit of data. The access switch 604 may be turned on in order to access MTJ 602, while the access switch 610 may be turned on in order to access MTJ 610. When the 3T1D2M memory cell 600 is accessed, its read switch 606 may be turned on. When writing ‘0’, the read switch 606 may alternatively be turned off.

As shown in FIG. 6B and FIG. 6C, first transistor 604 may be configured to be switched on by the word line WL_{A} and the third transistor 610 may be configured to be switched off by the further word line WL_{B} during writing a logic state of the first bit of data in the magnetic tunneling junction memory 602.

As shown in FIG. 6B, the second transistor 606 may be configured to be switched off by the input ACT so that a first write current flows from the second source line SL_{B} through the diode 608 and the first transistor 604 to the bit line BL_{A} to write a first logic state, e.g. ‘0’, of the first bit of data in the magnetic tunneling junction memory 602 upon a voltage at the second source line being higher than a voltage at the bit line. A substantial current may not flow through the further magnetic tunneling junction memory 612.

As shown in FIG. 6C, the second transistor 606 may be configured to be switched on by the input ACT so that a second write current may flow from the bit line BL_{A} through the first transistor 604 and the second transistor 606 to the first source line SL_{A} to write a second logic state, e.g. ‘1’, of the first bit of data in the magnetic tunneling junction memory 604 upon a voltage at the first source line being lower than the voltage at the bit line. A substantial current may not flow through the further magnetic tunneling junction memory 612.

In other words, the first transistor 604 may be activated while the third transistor 610 may be deactivated when writing to the first MTJ 602. Writing a first logic state such as a ‘0’ may include flowing a current through the diode 608, while deactivating the second transistor 606. On the other hand, writing a second logic state such as a ‘1’ may include activating the second transistor 606 so that a writing current flows through the second transistor 606. During write operations, only one MTJ in the 3T1D2M memory cell 600 may be programmed.

On the other hand, the first transistor 604 may be configured to be switched off by the word line WL_{A} and the third transistor 610 may be configured to be switched on by the further word line WL_{B} during writing a logic state of the second bit of data in the magnetic tunneling junction memory

The second transistor 606 may be configured to be switched off by the input ACT so that a third write current flows from the second source line SL_{B} through the diode 608 and the third transistor 610 to the further bit line BL_{B} to write a first logic state of the second bit of data in the further magnetic tunneling junction memory 610 upon the voltage at the second source line SL_{B} being higher than a voltage at the further bit line BL_{B}.

The second transistor 606 may be configured to be switched on by the input ACT so that a fourth write current flows from the further bit line BL_{B} through the third transistor 610 and the second transistor 606 to the first source line SL_{A} to write a second logic state of the second bit of data in the further magnetic tunneling junction memory 610 upon the voltage at the first source line SL_{A} being lower than the voltage at the further bit line BL_{B}.

In other words, the third transistor 610 may be activated while the first transistor 604 may be activated when writing to the second MTJ 612. Writing a first logic state such as a ‘0’ may include flowing a current through the diode 608, while deactivating the second transistor 606. On the other hand, writing a second logic state such as a′1′ may include activating the second transistor 606 so that a writing current flows through the second transistor 606.

FIGS. 6D-E shows the path of the read current I_{RD} through the memory cell 600.

FIG. 6D shows a schematic of the memory cell 600 shown in FIG. 6A in high density mode when reading a logic state of the magnetic tunneling junction memory 602 according to various embodiments.

During a read operation, the first transistor 604 may be configured to be switched on by the word line WL_{A}, the second transistor 606 may be configured to be switched on by the input ACT, and the third transistor 610 may be switched off by the further word line WL_{B} so that a first read current flows from the bit line BL_{A} through the first transistor 604 and the second transistor 606 to the first source line SL_{A} to determine a logic state of the first bit of data in the magnetic tunneling junction memory 602 upon a voltage at the bit line BL_{A} being higher than a voltage at the first source line SL_{A}.

FIG. 6E shows a schematic of the memory cell 600 shown in FIG. 6A in high density mode when reading a logic state of the further magnetic tunneling junction memory 612 according to various embodiments.

The first transistor 604 may be configured to be switched off by the word line WL_{A}, the second transistor 606 configured to be switched on by the input ACT, and the third transistor 610 may be switched on by the further word line WL_{B} so that a second read current flows from the further bit line BL_{B} through the third transistor 610 and the second transistor 606 to the first source line SL_{A} to determine a logic state of the second bit of data in the further magnetic tunneling junction memory 610 upon a voltage at the further bit line BL_{B} than the voltage at the first source line SL_{A}.

The resistance of only one MTJ in the 3T1D2M memory cell 600 may be sensed during one read operation. Just as in the 2T1D1M memory cell 500, voltage-based sensing scheme or current-based sensing scheme may be used to sense the resistance of the MTJ through which I_{RD} flows.

The description of the read and write operations of the 3T1D2M memory cell 600 relate to embodiments wherein only one of the two MTJs in the 3T1D2M memory cell 600 is accessed at any one instance. It may also be envisioned that the write and read operations of the 3T1D2M memory cell may be designed to allow simultaneous access to both MTJs during write operation and during read operation. However, a read operation may not be performed on one MTJ, when the other MTJ is being written.

FIG. 6F is a table showing the control voltages for reading and writing the first magnetic memory junction 602 of the memory cell 600 shown in FIG. 6A in high density mode according to various embodiments. FIG. 6F shows that writing a ‘0’ in the first MTJ 602 may alternatively include activating the second transistor 606 (ACT=VDD) and having a voltage at the first source line SL_{A} to be about the same potential as the second source line SL_{B} (SL_{A}=SL_{B}=V_{WR}), and higher than the first bit line (BL_{A}=GND) so that a supplementary write current may together with the first write current write the ‘0’ in the first MTJ 602. In addition, during a read operation, instead of having a voltage of the bit line BL_{A} higher than the first source line SL_{A} (BL_{A}=V_{RD}, SL_{A}=GND) as shown in FIG. 6D, various embodiments may have a voltage of the bit line BL_{A} lower than the first source line SL_{A} (BL_{A}=GND, SL_{A}=Van), so that the read current flows from the first source line SL_{A} to the bit line BL_{A}.

VDD may be of any suitable value. In various embodiments, VDD may be any suitable value selected from a range of 0.5 V to 1.5 V. V_{WR} may be of any suitable value. In various embodiments, V_{WR} may be any suitable value selected from a range of 0.5 V to 1.5 V. V_{RD} may be of any suitable value. In various embodiments, V_{RD} may be any suitable value selected from a range of 0.5 V to 1.5 V.

The control voltages for reading and writing the second magnetic memory junction 612 may be similar, with WL_{A} swapped with WL_{B}, and BL_{A} swapped with BL_{B}.

The sensing scheme of the 2T1D1M memory cell and high density operation mode 3T1D2M memory cell as described earlier may be single-ended in nature. The sensed resistance in the memory cell may be compared with a separate reference resistance.

The 3T1D2M may have a differential mode of operation. Differential sensing may be more robust and may be faster than single-ended sensing.

Differential mode of operation may sacrifice the density of memory storage to improve robustness against process variations and read access speed. In the differential mode of operation, the MTJs in each 3T1D2M memory cell may store both a bit of data with its complementary bit. In other words, the magnetic tunneling junction memory and the further magnetic tunneling junction memory may be configured to store a single bit of data.

Since both the bit and complementary bit are present, read operation of the 3T1D2M memory cell in differential mode of operation may occur by comparing the resistances of the MTJs in the memory cell with each other. For example, a ‘0’ is stored when R_{MTJ},A is larger than R_{MTJ},B, whereas a ‘1’ is stored when R_{MTJ},B is larger than R_{MTJ,A}.

The magnetic tunneling junction memory 602 may be configured to be in a first resistance state and the further magnetic tunneling junction memory 612 may be configured to be in a second resistance state to define a first logic state of the single bit of data. Further, the magnetic tunneling junction memory 602 may be configured to be in the second resistance state and the further magnetic tunneling junction memory 612 may be configured to be in the first resistance state to define a second logic state in the single bit of data.

In the current context, “logic state” may be used interchangeably with “resistance state”. However, the logic state or resistance state of a memory cell may be the same or may be different from the logic state or resistance state of magnetic tunneling junction included in the memory cell. For instance, the memory cell 600 in the differential mode of operation may be in the first logic state when the magnetic tunneling junction memory 602 is in the first logic state or resistance state, and the further magnetic tunneling junction memory 612 is in the second logic state or resistance state.

FIG. 6G shows a schematic of the memory cell 600 shown in FIG. 6A in differential mode during a read operation according to various embodiments. The read operation of the 3T1D2M memory cell in differential mode of operation may be described below. Both WL_{A} and WL_{B} may be charged to VDD so as to turn both the first transistor 604 and the third transistor 610 on. ACT may also be charged to VDD to switch the second transistor 606 on. A differential sense amplifier may be used to compare the resistance between BL_{A} and SL_{A} to that between BL_{B} and SL_{A}. Since the MTJs 602, 612 store complementary data, R_{MTJ},A may be of low resistance when R_{MTJ,B} is of high resistance, vice versa. Thus, the resistance between BL_{A} and SL_{A} may be low when the resistance between BL_{B} and SL_{A} is high, vice versa. Just as in the 2T1D1M memory cell, either a voltage-based sensing scheme or a current-based sensing scheme may be used to determine the relative values of R_{MTJ},A and R_{MTJ},B.

In other words, the memory cell 600 may further include a sense amplifier configured to determine a resistance state of the magnetic tunneling junction memory 602, and to determine a resistance state of the further magnetic tunneling junction memory 612 to determine a logic state of the single bit of data.

The first transistor 604 may be configured to be turned on, the second transistor 606 may be configured to be turned on, and the third transistor 610 may be configured to be turned on so that a first read current flows from the bit line BL_{A} to the first source line SL_{A} to determine the resistance state of the magnetic tunneling junction memory 602 upon a voltage at the bit line BL_{A} higher than a voltage at the first source line SL_{A}, and a second read current flows from the further bit line BL_{B} to the first source line SL_{A} to determine the resistance state of the further magnetic tunneling junction memory 612 upon a voltage at the further bit line BL_{B} higher than the voltage at the first source line SL_{A}. The resistance state of the magnetic tunneling junction memory 602 may be different from the resistance state of the further magnetic tunneling junction memory 612.

The sense amplifier may be configured to determine the logic state of the single bit of data based on the resistance state of the magnetic tunneling junction memory 602 and the resistance state of the further magnetic tunneling junction memory 612.

The resistance state of a MTJ may be determined by determining a read current passing through the MTJ upon application of a fixed voltage, or determining a read voltage across the MTJ upon application of a fixed current. For instance, equal voltages may be applied between the bit line BL_{A} and the first source line SL_{A} as well as between the further bit line BL_{B} and the first source line SL_{A}. The first read current may be of different magnitude compared to the second read current due to the resistance state of the magnetic tunneling junction memory 602 being different from the resistance state of the further magnetic tunneling junction memory 612. The sense amplifier may be configured to receive the first read current and the second read current, and may be configured to determine the logic state of the memory cell 600 based on the first read current and the second read current. In another example, the first read current and the second read current may be of equal magnitude. A first read voltage (or potential difference) may be determined between the bit line BL_{A} and the first source line SL_{A}, and a second read voltage (or potential difference) may be determined between the further bit line BL_{B} and the first source line SL_{A}. The sense amplifier may be configured to receive the first read voltage (or potential difference) and the second read voltage (or potential difference), and may be configured to determine the logic state of the memory cell 600 based on the first read voltage (or potential difference) and the second read voltage (or potential difference).

The write operation of the 3T1D2M memory cell in differential mode of operation may be achieved using a sequence of write operations of the 3T1D2M memory cell in high density mode.

The write current flow during these write operations are shown in FIGS. 6B-C. ‘0’ may be written into the 3T1D2M memory cell in differential mode in a similar manner by first selecting the MTJ 602 to write ‘0’ and then selecting the further MTJ 612 to write ‘1’. Similarly, ‘1’ may be written into the 3T1D2M memory cell in differential mode by first selecting the MTJ 602 to write 1′, and then selecting the further MTJ 612 to write ‘0’. The order of writing the MTJ 602 and the further MTJ 612 may not matter.

Also, since the read operation of the 3T1D2M memory cell may be very fast compared to the write operation, the MTJ 602 and the further MTJ 612 may be sensed prior to write operation without incurring performance penalty.

Knowing the resistance state of the MTJ 602, R_{MTJ,}A, and the resistance state of the further MTJ 612, R_{MTJ,B}, prior to write operation may allow the write control logic to determine whether the state of the memory cell 600 would need to be altered. The write operation to the memory cell may be terminated if the state of the memory cell does not need to be altered, which reduces write energy consumption.

An alternative scheme for write operations for the 3T1D2M memory cell 600 in differential mode may include first executing a clear operation. FIG. 6H shows a schematic of the memory cell 600 shown in FIG. 6A in differential mode during a clear operation according to various embodiments. The clear operation may write both the MTJ 602 and the further MTJ 612 with ‘1’.

In other words, the resistance state of the magnetic tunneling junction memory 602 and the resistance state of the further tunneling junction memory 612 may be configured to be the same to define a clear state in the single bit of data. The first transistor 604 may be configured to be turned on, the second transistor 606 may be configured to be turned off, and the third transistor 610 may be configured to be turned on so that a first clear current flows from the second source line through the diode 608 and the first transistor 608 to the bit line BL_{A} when a voltage at the second source line SL_{B} is higher than a voltage at the bit line BL_{A}, and a second clear current flows from the second source line SL_{B} through the diode 608 and the third transistor 610 to the further bit line BL_{B} when the voltage at the second source line SL_{B} is higher than a voltage at the further bit line BL_{B} to write the same resistance state, e.g. a ‘1’, to the magnetic tunneling junction memory 602 and the further tunneling junction memory 612.

After the completion of the clear operation, one MTJ of the MTJs 602, 612 may be selected to write a ‘0’ using the scheme shown in FIGS. 6B-C. Alternatively, a ‘0’ may be written to the one MTJ selected from MTJs 602, 612 as illustrated by FIGS. 6I-J as shown below.

FIG. 6I shows a schematic of the memory cell 600 shown in FIG. 6A during a differential write operation to write a first logic state to the memory cell 600 according to various embodiments. FIG. 6J shows a schematic of the memory cell 600 shown in FIG. 6A during another differential write operation to write a second logic state to the memory cell 600 according to various embodiments. The differential write operations shown in FIGS. 6I-J may be carried out after the clear operation shown in FIG. 6H.

The control voltages across the 3T1D2M memory cell 600 may be set such that the first transistor 604, the second transistor 606, and the third transistor 610 are turned on. As shown in FIG. 6I, during writing a ‘0’, a write current, Iw_{R}, may be sourced through the bit line BL_{A}. The write current I_{WR} may pass through the MTJ 602 and may be split into a first sub-current flowing to and sinked by the first source line SL_{A} and a second sub-current flowing to and sinked by the further bit line BL_{B}. The resistance state of the MTJ 602 may be switched, i.e. from ‘1’ to ‘0’, while the resistance state of the further MTJ 612 may remain at ‘1’. As a result, the logic state of the memory cell 600 may be switched from a clear state (with both MTJs 602, 612 at ‘1’) to ‘0’.

If ‘1’ is to be written instead, as shown in FIG. 6J, the write current I_{WR} may be sourced from the further bit line BL_{B}. The write current I_{WR} may pass through the further MTJ 612 and may be split into a first sub-current flowing to and sinked by the bit line BL_{A} and a second sub-current flowing to and sinked by the first source line SL_{A}. The resistance state of the further MTJ 612 may be switched, i.e. from 1′ to ‘0’, while the resistance state of the MTJ 602 may remain at V. As a result, the logic state of the memory cell 600 may be switched from a clear state (with both MTJs 602, 612 at ‘1’) to ‘0’.

In other words, the first transistor 604 may be configured to be switched on by the word line WL_{A}, the second transistor 606 may be configured to be switched on by the input ACT, and the third transistor 610 may be configured to be switched on by the further word line WL_{B} to define the first logic state, e.g. ‘0’, in the memory cell 600, by flowing a first write current (first sub-current shown in FIG. 6I) from the bit line BL_{A} to the first source line SL_{A} when a voltage at the bit line BL_{A} is higher than a voltage at the first source line SL_{A} and flowing a second write current (second sub-current shown in FIG. 6I) from the bit line BL_{A} to the further bit line BL_{B} when the voltage at the bit line BL_{A} is higher than a voltage at the further bit line BL_{B}, and to define the second logic state, e.g. ‘1’, in the memory cell 600, by flowing a third write current (first sub-current shown in FIG. 6J) from the further bit line BL_{B} to the first source line SL_{A} when the voltage at the further bit line BL_{B} is higher than the voltage at the first source line SL_{A} and flowing a fourth write current (second sub-current shown in FIG. 6J) from the further bit line BL_{B} to the bit line BL_{A} when the voltage at the further bit line BL_{B} is higher than the voltage at the bit line BL_{A}.

Note that the current flows in FIGS. 6I-J is oriented in such a way that ‘0’ is written in one MTJ while a ‘1’ may be written in another MTJ. As such, if the write current for writing the ‘1’ in the other MTJ is sufficiently large, the clear operation prior to the write operation may be redundant and may be eliminated to save on write energy and reduce delay.

FIG. 6K is a table showing the control voltages for read and clear operations of the memory cell 600 shown in FIG. 6A in differential mode according to various embodiments. For each memory cell operation, square brackets indicate the set of alternative voltages that may be used on the corresponding control terminal. For instance, in a read operation, the first source line may be at ground (GND) or at a predetermined read voltage V_{RD,3}. V_{RD,3} may be lower or higher than V_{RD,1} or/and V_{RD,2}. In a clear operation, the second transistor 606 may be activated (ACT=VDD) or may be deactivated (as described in relation to FIG. 6H, ACT=GND). When the second transistor 606 is deactivated, the first source line SL_{A} may be at ground (SLA=GND), so that the first clear current flowing through the first transistor 604 and the second clear current through the third transistor 610 may be only from the second source line SL_{B} (through the diode 608). On the other hand, when the second transistor 606 is activated and the first source line SL_{A} is at a voltage higher than a voltage at the bit line BL_{A} as well as higher than a voltage at the further bit line BL_{B}, the first clear current and the second clear current may be contributed by both the first source line SL_{A} and the second source line SL_{B}.

FIG. 6L is a table showing the control voltages for writing to the memory cell 600 as shown in FIGS. 6I-J according to various embodiments.

Various embodiments may have advantages over other cell architectures.

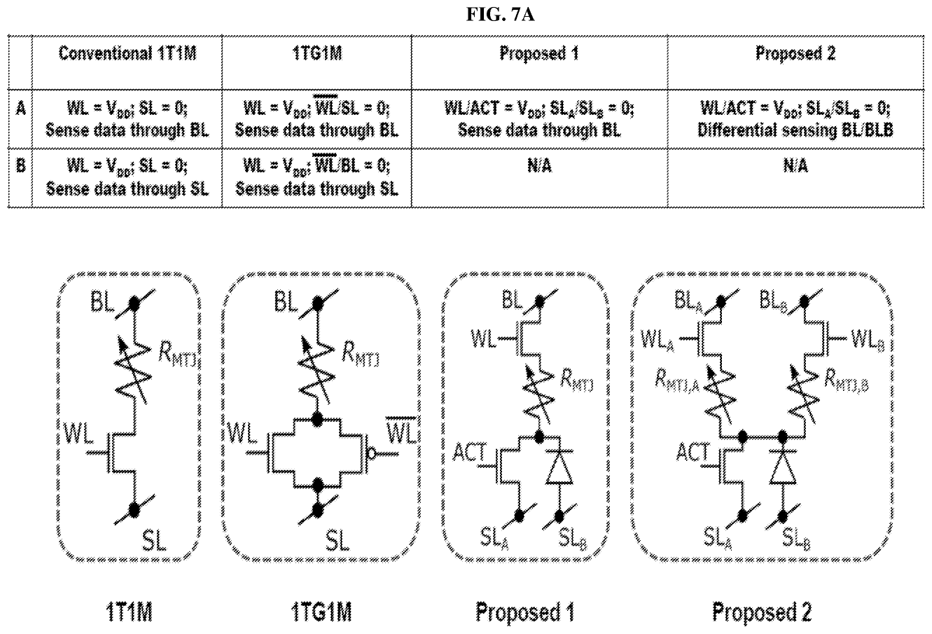

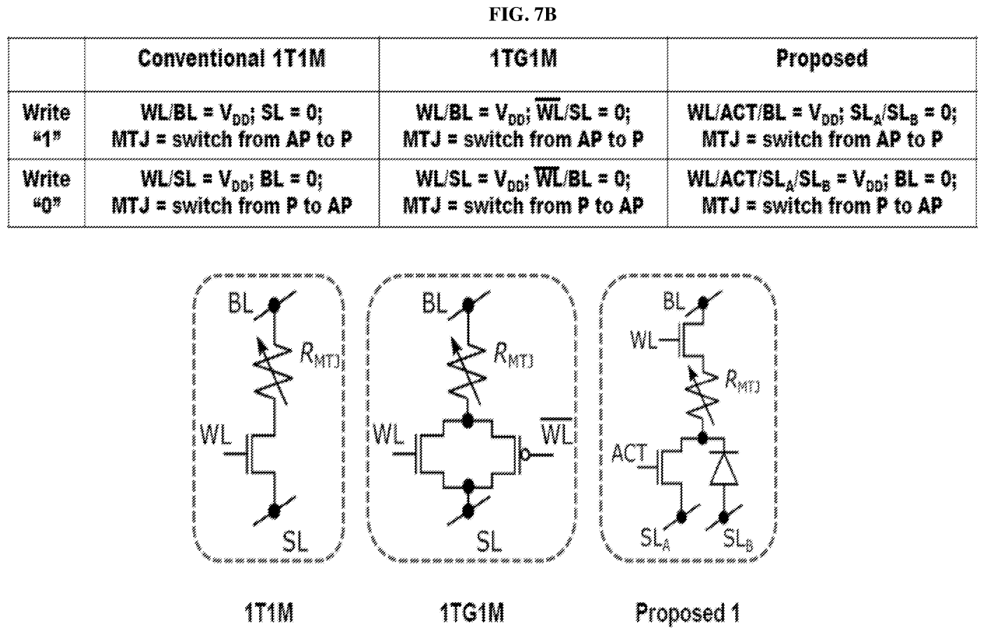

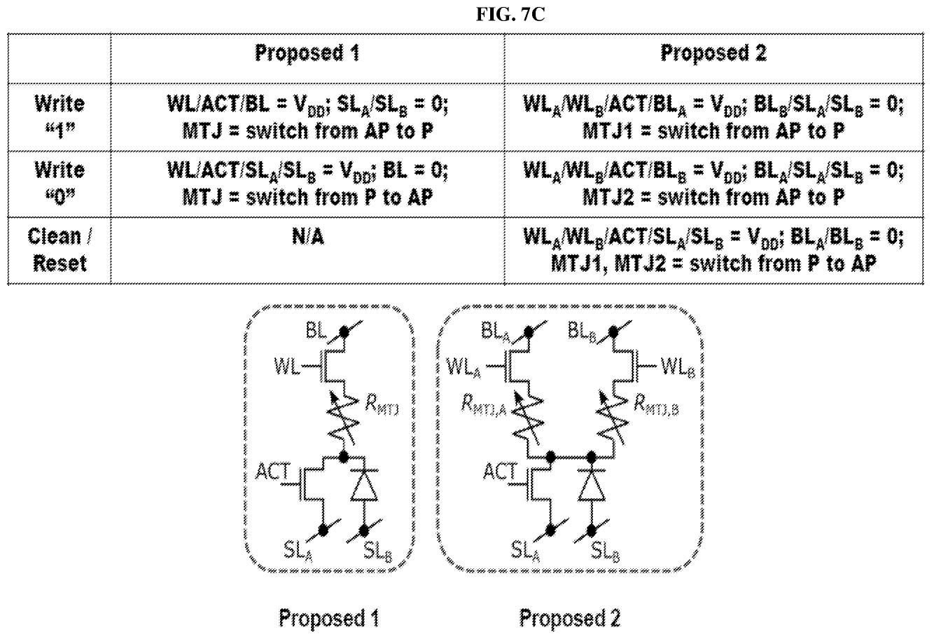

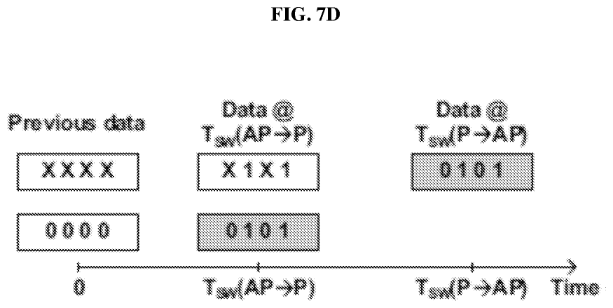

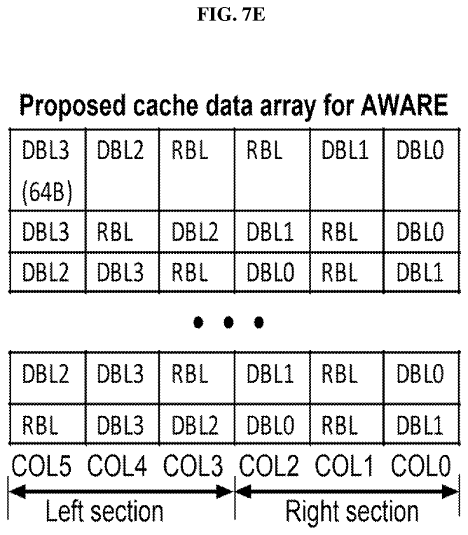

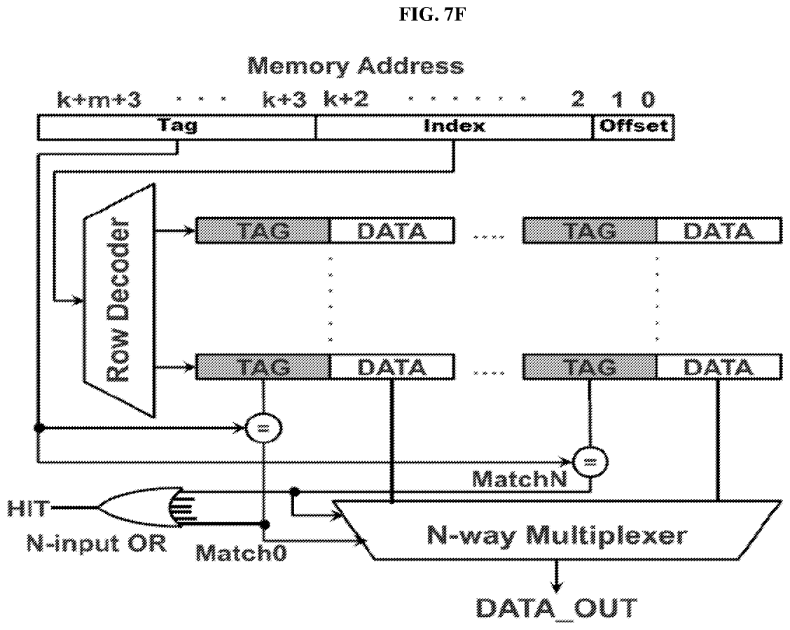

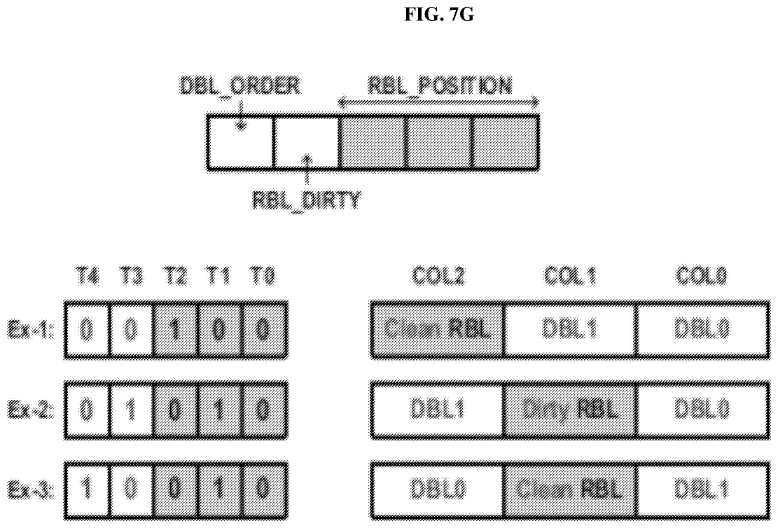

FIG. 7A compares the memory cells shown in FIG. 5A (Proposed 1) and FIG. 6A (Proposed 2) with a 1-transistor-1-magnetic tunneling junction (1T1M) cell architecture and a 1-transmission gate-1-magnetic tunneling junction (1TG1M) cell architecture during a read operation.

FIG. 7B compares the memory cells shown in FIG. 5A (Proposed 1) with a 1-transistor-1-magnetic tunneling junction (1T1M) cell architecture and a 1-transmission gate-1-magnetic tunneling junction (1TG1M) cell architecture during a write operation. The cell may store data based on the resistance of the MTJ.

FIG. 7C compares the memory cells shown in FIG. 5A (Proposed 1) and FIG. 6A (Proposed 2) during write operations and a clean/reset operation. As highlighted above, the memory cell may either store two bits of data, or a single bit of data (based on complementary data stored in each MTJ).

Various embodiments may relate to a memory array including a plurality of memory cells as described herein. A write operation may be used to write a ‘0’ or a ‘1’. A delay to the write operation may be attributable to the slower step between the step of writing a ‘0’ and the step of writing a ‘1’.

Various embodiments may make use of the AWARE-cache method proposed by Kwon et al. (IEEE Trans. VLSI, Vol. 22, No. 4, pp. 712-720, April 2014), incorporated herein in its entirety for all purposes, to remove redundant blocks (RBL) in a cache line to improve effective write latency.

FIG. 7D is a schematic illustrating the AWARE-cache method which may be employed by a memory array according to various embodiments. FIG. 7E is another schematic illustrating the AWARE-cache method which may be employed by a memory array according to various embodiments.

FIG. 7F illustrates a conventional cache operation. FIG. 7G illustrates an array operation for a 3-transistors-1-magnetic tunneling junction (3T1MTJ) cell or a 4-transistors-2-magnetic tunneling junctions (4T2MTJ) cell. The cache line containing block to be written is first checked if there is a “CLEAN” RBL. If there is a “CLEAN” RBL, the block to be written may be marked as “Dirty” RBL and to data to be written may be stored in the “CLEAN” RBL. The tag store of the cache may be updated.

If there is no “CLEAN” RBL, the data may be written directly to the target block. A “CLEAN” operation may be performed on any “Dirty” RBL.

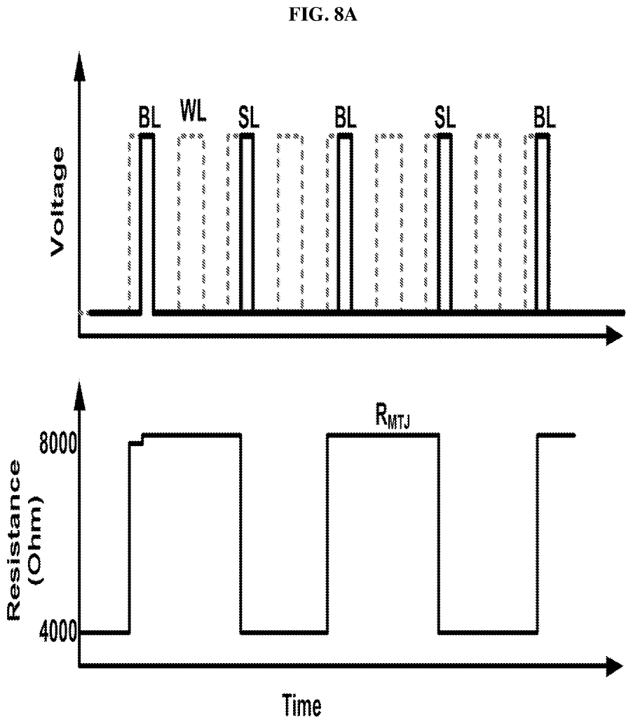

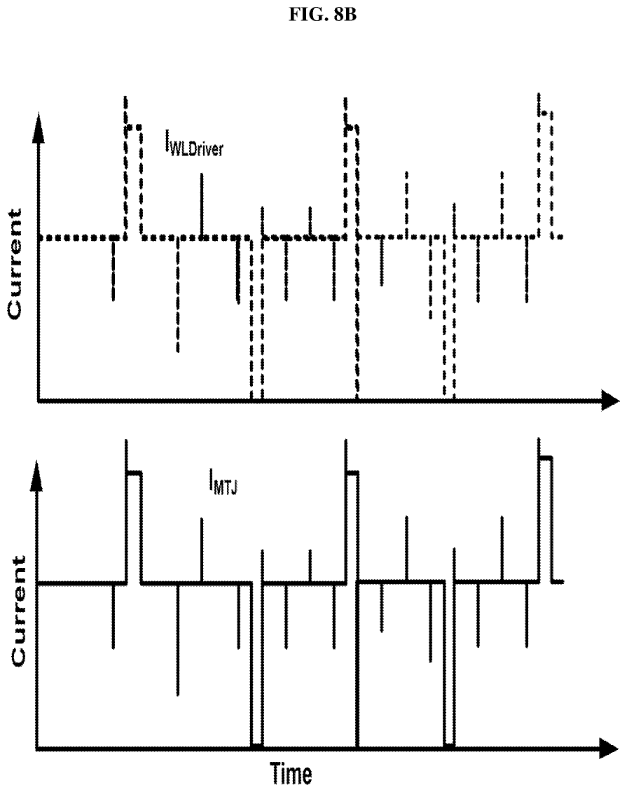

A simulation is performed to simulate the operation of the memory cell shown in FIG. 5A. FIGS. 8A-B, 9A-B are intended to illustrate the operation of the memory cell. The specific voltages, currents and time values are not intended to be limiting, and may vary for different cases.

FIG. 8A shows (above) a plot of voltage as a function of time applied to the control terminals of the memory cell shown in FIG. 5A to show sequential write and hold operations according to various embodiments, and (below) a plot of resistance (in kilo-ohms or kΩ) as a function of time showing the resistance state of the memory cell shown in FIG. 5A according to various embodiments. In this simulation, ‘0’ and 1′ correspond to the high resistance state (HRS) and the low resistance state (LRS) respectively. Furthermore, the 2T1D1M memory cell may be arranged as part of a 4×4 memory array, wherein the WL is shared among memory cells forming a row and the BL is shared among the memory cells forming a column in the array. As shown in FIG. 8A, the applied voltages successfully switch the stored bit between ‘0’ and ‘1’.

The current supplied by the BL driver may also be compared to the current flowing through the MTJ of the memory cell selected in the array to ensure that sneak current paths are absent. The presence of sneak current paths in the array may cause the memory array to fail, as in the case of resistive crossbar arrays. The currents flowing through the MTJ of the selected memory cell and the current supplied by the BL driver are shown in FIG. 8B. FIG. 8B is a plot of current as a function of time showing the currents supplied by the voltage source driving the bitline as well as the current flowing through the magnetic tunneling junction of the memory cell shown in FIG. 5A according to various embodiments.

Glitches in the driver current may occur if there is a delay before the voltage of BL settles. FIG. 8B shows that the current flowing through the selected MTJ is the same as that supplied by the BL driver. Hence, we may conclude there are no sneak current paths in the array.

A simulation is performed to simulate the operation of the memory cell shown in FIG. 6A.

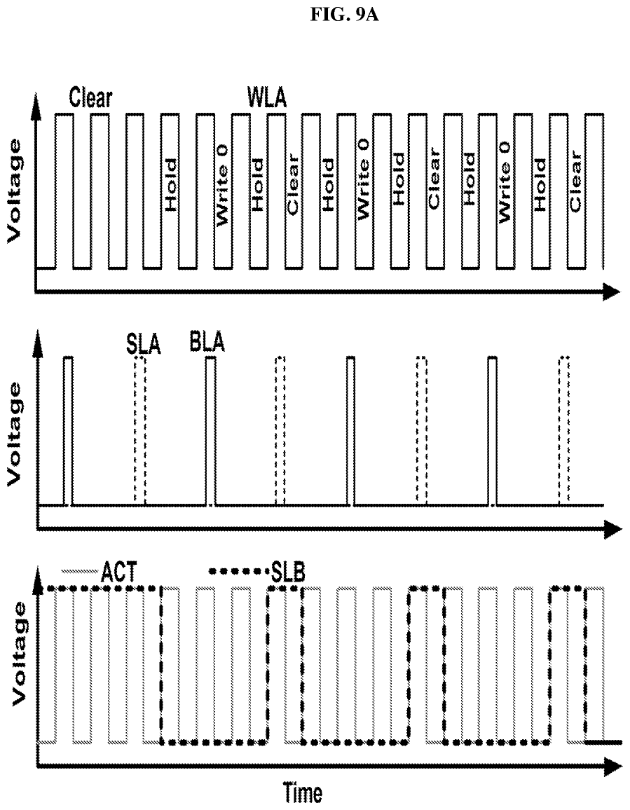

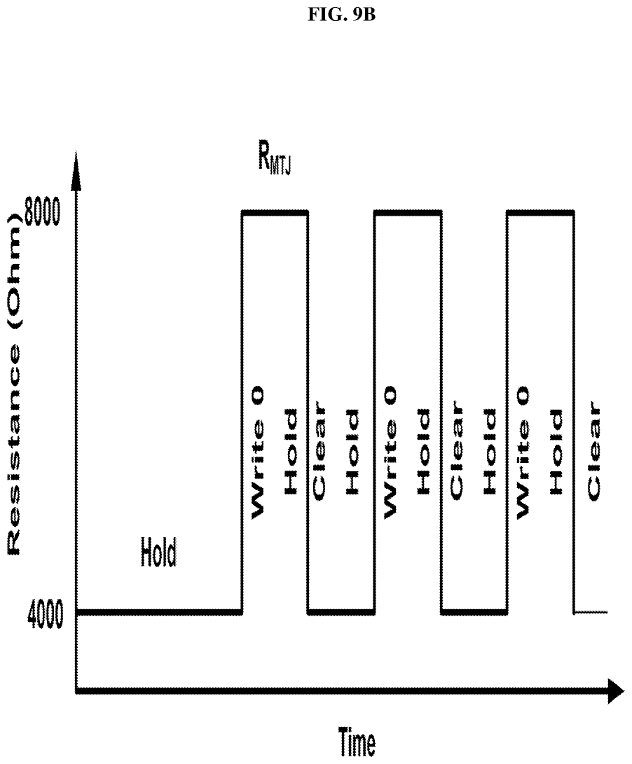

FIG. 9A shows (top) a plot of voltage as a function of time illustrating the voltage applied to the word line (WL_{A}) of the memory cell shown in FIG. 6A for sequential write and hold operations; (middle) a plot of voltage as a function of time illustrating the voltage applied to the bit line (BL_{A}) and the first source line (SL_{A}) of the memory cell shown in FIG. 6A for sequential write and hold operations; and (bottom) a plot of voltage as a function of time illustrating the voltage applied to the second source line (SL_{B}) and the input (ACT) of the memory cell shown in FIG. 6A for sequential write and hold operations.

The 3T1D2M memory cell may be arranged as part of a 4×4 memory array. BL_{A}, BL_{B}, SL_{A}, and SL_{B} connect memory cells in a column of the array. The word and ACT lines connect memory cells in a row of the array. WL_{A} and WL_{B} are connected to a common word line, which has the voltage waveform shown as V_{WL}. The waveforms in FIG. 9A shows that the clear operation is first performed to set both MTJs in the 3T1D2M memoy cell into the high resistance state (HRS). Then, several cycles of operations are performed. Each cycle of operations begin with a write operation, followed by a hold operation and then the clear operation. The data written into the memory cell in consecutive cycles is different.

FIG. 9B shows a plot of resistance (in ohms or Ω) as a function of time showing the resistance state of the memory cell shown in FIG. 6A according to various embodiments. The waveforms show that R_{MTJ,A} and R_{MTJ,B} are successfully switched between HRS and LRS (R_{AP} and R_{P}, respectively) during the write and clear operations.

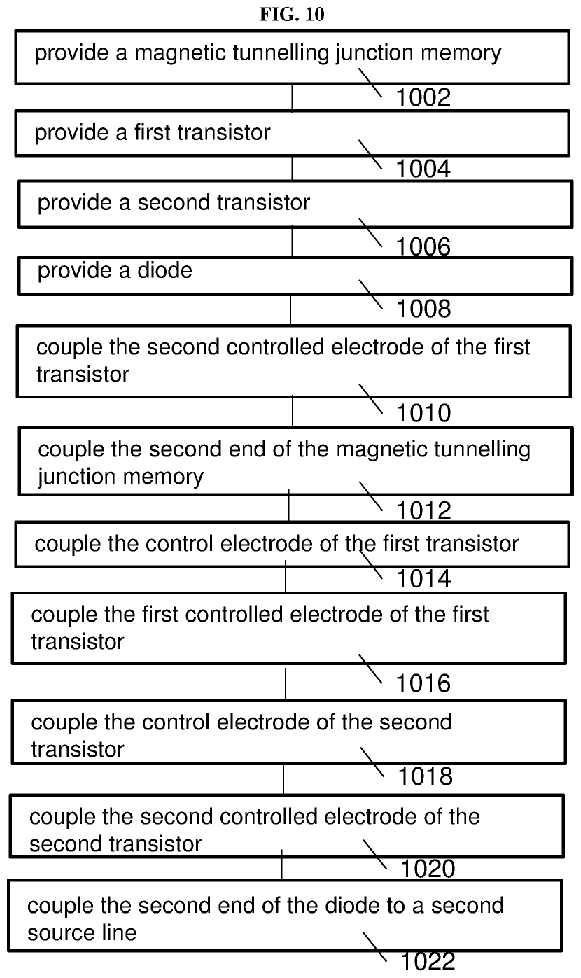

FIG. 10 shows a schematic of a method of forming a memory cell according to various embodiments. The method may include, in 1002, providing a magnetic tunneling junction memory including a first end and a second end. The method may also include, in 1004, providing a first transistor including a control electrode, a first controlled electrode and a second controlled electrode. The method may further include, in 1006, providing a second transistor including a control electrode, a first controlled electrode and a second controlled electrode. The method may additionally include, in 1008, providing a diode having a first end and a second end.

The method may further include, in 1010, coupling the second controlled electrode of the first transistor to the first end of the magnetic tunneling junction memory. The method may also include, in 1012, coupling the second end of the magnetic tunneling junction memory to the first controlled electrode of the second transistor and the first end of the diode. The method may additionally include, in 1014, coupling the control electrode of the first transistor to a word line. The method may also include, in 1016, coupling the first controlled electrode of the first transistor to a bit line. The method may further include, in 1018, coupling the control electrode of the second transistor to an input. The method may additionally include, in 1020, coupling the second controlled electrode of the second transistor to a first source line. The method may also include, in 1022, coupling the second end of the diode to a second source line.

In other words, the method may include connecting the magnetic tunneling junction memory, the first transistor, the second transistor, and the diode to form a memory cell.

The memory cell may be the memory cell shown in FIG. 5A.

The method may further include providing a third transistor including a control electrode, a first controlled electrode and a second controlled electrode. The method may also include providing a further magnetic tunneling junction memory including a first end and a second end. The method may additionally include coupling the second controlled electrode of the third transistor to the first end of the further magnetic tunneling junction memory. The method may further include coupling the second end of the further magnetic tunneling junction memory to the second end of the magnetic tunneling junction memory. The second end of the further magnetic tunneling junction memory may also be coupled to the first controlled electrode of the second transistor, and the first end of the diode. The method may also include coupling the control electrode of the third transistor to a further word line. The method may additionally include coupling the first controlled electrode of the third transistor to a further bit line.

The memory cell may be the memory cell shown in FIG. 6A.

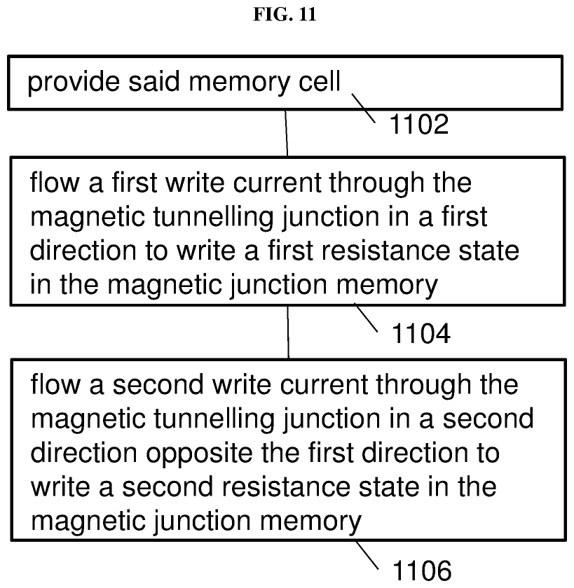

FIG. 11 shows a schematic of a method of operating a memory cell according to various embodiments. The method may include, in 1102, providing said memory cell. The memory cell may include a magnetic tunneling junction memory including a first end and a second end. The memory cell may also include a first transistor including a control electrode, a first controlled electrode and a second controlled electrode. The memory cell may further include a second transistor including a control electrode, a first controlled electrode and a second controlled electrode. The memory cell may additionally include a diode having a first end and a second end.

The method may also include, in 1104, flowing or passing a first write current through the magnetic tunneling junction in a first direction to write a first logic state in the magnetic junction memory. The first write current may flow from the first transistor, through the magnetic tunneling junction to the second transistor. The method may include activating the first transistor and the second transistor to flow or pass the first write current.

The method may additionally include, in 1106, flowing or passing a second write current through the magnetic tunneling junction in a second direction opposite the first direction to write a second logic state in the magnetic junction memory. The second write current may flow from the diode, through the magnetic tunneling junction to the first transistor. A supplementary write current may also flow from the second transistor to the first transistor. In other words, both the second write current and supplementary write current may flow in the same direction through the magnetic tunneling junction. In various embodiments, the method may include activating the second transistor so that the supplementary write current may flow from the second transistor to the first transistor. In various embodiments, the second transistor may be deactivated so that only the second write current flows through the magnetic tunnel junction.

The method may include, flowing or passing a read current. The method may include activating the first transistor and the second transistor so that the read current may flow from the first transistor through the magnetic tunneling junction to the second transistor, or from the second transistor through the magnetic tunneling junction to the first transistor. In various embodiments, the read current may be fixed. The method may include determining a read voltage (at a point along a path of the read current) so that a logic state of the magnetic tunneling junction may be determined by determining a resistance value of the magnetic tunneling junction. In various other embodiments, a fixed voltage may be applied between two points (along the path of the read current), with the magnetic tunneling junction between the two points. The method may include determining the read current so that a logic state of the magnetic tunneling junction may be determined by determining a resistance value of the magnetic tunneling junction.

In various embodiments, the memory cell may further include a third transistor including a control electrode, a first controlled electrode and a second controlled electrode. The memory cell may also include a further magnetic tunneling junction memory including a first end and a second end. The second controlled electrode of the third transistor may be coupled to the first end of the further magnetic tunneling junction memory. The second end of the further magnetic tunneling junction memory may be coupled to the second end of the magnetic tunneling junction memory. The control electrode of the third transistor may be configured to be coupled to a further word line. The first controlled electrode of the third transistor may be configured to be coupled to a further bit line.

The method may further include passing or flowing a third write current through the further magnetic tunneling junction in a first direction to write a first logic state in the further magnetic junction memory. The method may also include passing or flowing a fourth write current through the further magnetic tunneling junction in a second direction opposite the first direction to write a second logic state in the further magnetic junction memory.

In various embodiments, the memory cell may be in a high-density mode. In various embodiments, the magnetic tunneling junction memory may be configured to store a first bit, and the further magnetic tunneling junction memory may be configured to store a second bit.

In various embodiments, the memory cell may be in a differential mode. In various embodiments, the magnetic tunneling junction memory may be configured to be in the first logic state and the further magnetic tunneling junction memory may be configured to be in the second logic state to define a first logic state of the memory cell. In various embodiments, the magnetic tunneling junction memory may be configured to be in the second logic state and the further magnetic tunneling junction memory may be configured to be in the first logic state to define a second logic state of the memory cell.

Various embodiments may be cost effective, low power and/or easy to implement. Various embodiments may be robust and scalable. Various embodiments may be suitable for a large class of application. Various embodiments may be a good candidate to replace SRAM as a last-level cache. Various embodiments may have high throughput. Various embodiments may be easy switch between a differential mode and a high density mode.

Various embodiments may relate to a MRAM cell design Various embodiments may relate to cell operation. Various embodiments may relate to a sensing method for differential cell. Various embodiments may relate to a write method for a cell structure. Various embodiments may relate to a MRAM array architecture. Various embodiments may relate to a memory cell or array in differential mode. Various embodiments may relate to a memory cell or array in high density mode.

Various embodiments may have more sensing margin compared to a 1T1M cell. Various embodiments may require less power than a 2T2M cell.

Various embodiments may be traced using a scanning electron microscopy (SEM) microscope.

Various embodiments may employ standard fabrication steps. Various embodiments may not require additional masks. Various embodiments may have reduced circuit complexity. Various embodiments may have design requirements and interfaces similar to conventional designs. Various embodiments may have a more relaxed amplifier design requirement due to improved noise margin of the differential signal.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A memory cell comprising:
a magnetic tunneling junction memory including a first end and a second end;
a first transistor including a control electrode, a first controlled electrode and a second controlled electrode;
a second transistor including a control electrode, a first controlled electrode and a second controlled electrode; and
a diode having a first end and a second end;
wherein the second controlled electrode of the first transistor is coupled to the first end of the magnetic tunneling junction memory;
wherein the second end of the magnetic tunneling junction memory is coupled to the first controlled electrode of the second transistor and the first end of the diode;
wherein the control electrode of the first transistor is configured to be coupled to a word line;
wherein the first controlled electrode of the first transistor is configured to be coupled to a bit line;
wherein the control electrode of the second transistor is configured to be coupled to an input;
wherein the second controlled electrode of the second transistor is configured to be coupled to a first source line; and
wherein the second end of the diode is configured to be coupled to a second source line.

2. The memory cell according to claim 1,
wherein the first transistor is configured to be switched on by the word line and the second transistor is configured to be switched on by the input so that a first write current flows from the bit line through the first transistor and the second transistor to the first source line to write a first logic state in the magnetic tunneling junction memory; and
wherein the first transistor is configured to be switched on by the word line and the second transistor is configured to be switched off by the input so that a current flows from the second source line through the diode and the first transistor to the bit line to write a second logic state in the magnetic tunneling junction memory.

3. The memory cell according to claim 1,
wherein the first transistor is configured to be switched on by the word line and the second transistor is configured to be switched on by the input so that a read current flows from the bit line through the first transistor and the second transistor to the first source line to determine a logic state in the magnetic tunneling junction memory.

4. The memory cell according to claim 1, further comprising:
a third transistor including a control electrode, a first controlled electrode and a second controlled electrode; and
a further magnetic tunneling junction memory including a first end and a second end;
wherein the second controlled electrode of the third transistor is coupled to the first end of the further magnetic tunneling junction memory;
wherein the second end of the further magnetic tunneling junction memory is coupled to the second end of the magnetic tunneling junction memory;
wherein the control electrode of the third transistor is configured to be coupled to a further word line, and
wherein the first controlled electrode of the third transistor is configured to be coupled to a further bit line.

5. The memory cell according to claim 4,
wherein the magnetic tunneling junction memory is configured to store a first bit of data and the further magnetic tunneling junction memory is configured to store a second bit of data.

6. The memory cell according to claim 5,
wherein the first transistor is configured to be switched on by the word line and the third transistor is configured to be switched off by the further word line during writing a logic state of the first bit of data in the magnetic tunneling junction memory; and
wherein the first transistor is configured to be switched off by the word line and the third transistor is configured to be switched on by the further word line during writing a logic state of the second bit of data in the magnetic tunneling junction memory.

7. The memory cell according to claim 6,
wherein the second transistor is configured to be switched off by the input so that a first write current flows from the second source line through the diode and the first transistor to the bit line to write a first logic state of the first bit of data in the magnetic tunneling junction memory upon a voltage at the second source line being higher than a voltage at the bit line; and
wherein the second transistor is configured to be switched on by the input so that a second write current flows from the bit line through the first transistor and the second transistor to the first source line to write a second logic state of the first bit of data in the magnetic tunneling junction memory upon a voltage at the first source line being lower than the voltage at the bit line.

8. The memory cell according to claim 7,
wherein the second transistor is configured to be switched off by the input so that a third write current flows from the second source line through the diode and the third transistor to the further bit line to write a first logic state of the second bit of data in the further magnetic tunneling junction memory upon the voltage at the second source line being higher than a voltage at the further bit line; and
wherein the second transistor is configured to be switched on by the input so that a fourth write current flows from the further bit line through the third transistor and the second transistor to the first source line to write a second logic state of the second bit of data in the further magnetic tunneling junction memory upon the voltage at the first source line being lower than the voltage at the further bit line.

9. The memory cell according to claim 5,
wherein the first transistor is configured to be switched on by the word line, the second transistor is configured to be switched on by the input, and the third transistor is switched off by the further word line so that a first read current flows from the bit line through the first transistor and the second transistor to the first source line to determine a logic state of the first bit of data in the magnetic tunneling junction memory upon a voltage at the bit line being higher than a voltage at the first source line; and
wherein the first transistor is configured to be switched off by the word line, the second transistor is configured to be switched on by the input, and the third transistor is switched on by the further word line so that a second read current flows from the further bit line through the third transistor and the second transistor to the first source line to determine a logic state of the second bit of data in the further magnetic tunneling junction memory upon a voltage at the further bit line than the voltage at the first source line.

10. The memory cell according to claim 4,
wherein the magnetic tunneling junction memory and the further magnetic tunneling junction memory are configured to store a single bit of data.

11. The memory cell according to claim 10,
wherein the magnetic tunneling junction memory is configured to be in a first resistance state and the further magnetic tunneling junction memory is configured to be in a second resistance state to define a first logic state of the single bit of data; and
wherein the magnetic tunneling junction memory is configured to be in the second resistance state and the further magnetic tunneling junction memory is configured to be in the first resistance state to define a second logic state in the single bit of data.

12. The memory cell according to claim 11, further comprising:
a sense amplifier configured to determine a resistance state of the magnetic tunneling junction memory, and to determine a resistance state of the further magnetic tunneling junction memory to determine a logic state of the single bit of data; and
wherein the first transistor is configured to be turned on, the second transistor is configured to be turned on, and the third transistor is configured to be turned on so that a first read current flows from the bit line to the first source line to determine the resistance state of the magnetic tunneling junction memory upon a voltage at the bit line higher than a voltage at the first source line, and a second read current flows from the further bit line to the first source line to determine the resistance state of the further magnetic tunneling junction memory upon a voltage at the further bit line higher than the voltage at the first source line.

13. The memory cell according to claim 11,
wherein the resistance state of the magnetic tunneling junction memory and the resistance state of the further tunneling junction memory are configured to be the same to define a clear state in the single bit of data;
wherein the first transistor is configured to be turned on, the second transistor is configured to be turned off, and the third transistor is configured to be turned on so that a first clear current flows from the second source line through the diode and the first transistor to the bit line when a voltage at the second source line is higher than a voltage at the bit line, and a second clear current flows from the second source line through the diode and the third transistor to the further bit line when the voltage at the second source line is higher than a voltage at the further bit line to write the same resistance state to the magnetic tunneling junction memory and the further tunneling junction memory.

14. The memory cell according to claim 11,
wherein the first transistor is configured to be switched on by the word line, the second transistor is configured to be switched on by the input, and the third transistor is configured to be switched on by the further word line to define the first logic state by flowing a first write current from the bit line to the first source line when a voltage at the bit line is higher than a voltage at the first source line and flowing a second write current from the bit line to the further bit line when the voltage at the bit line is higher than a voltage at the further bit line, and to define the second logic state by flowing a third write current from the further bit line to the first source line when the voltage at the further bit line is higher than the voltage at the first source line and flowing a fourth write current from the further bit line to the bit line when the voltage at the further bit line is higher than the voltage at the bit line.

15. A method of forming a memory cell, the method comprising:
providing a magnetic tunneling junction memory including a first end and a second end;
providing a first transistor including a control electrode, a first controlled electrode and a second controlled electrode;
providing a second transistor including a control electrode, a first controlled electrode and a second controlled electrode;
providing a diode having a first end and a second end;
coupling the second controlled electrode of the first transistor to the first end of the magnetic tunneling junction memory;
coupling the second end of the magnetic tunneling junction memory to the first controlled electrode of the second transistor and the first end of the diode;
coupling the control electrode of the first transistor to a word line;
coupling the first controlled electrode of the first transistor to a bit line;
coupling the control electrode of the second transistor to an input;
coupling the second controlled electrode of the second transistor to a first source line; and
coupling the second end of the diode to a second source line.

16. The method of claim 15, further comprising:
providing a third transistor including a control electrode, a first controlled electrode and a second controlled electrode;
providing a further magnetic tunneling junction memory including a first end and a second end;
coupling the second controlled electrode of the third transistor to the first end of the further magnetic tunneling junction memory;
coupling the second end of the further magnetic tunneling junction memory to the second end of the magnetic tunneling junction memory;
coupling the control electrode of the third transistor to a further word line; and
coupling the first controlled electrode of the third transistor to a further bit line.

17. A method of operating a memory cell, the method comprising:
providing said memory cell comprising:
a magnetic tunneling junction memory including a first end and a second end;
a first transistor including a control electrode, a first controlled electrode and a second controlled electrode;
a second transistor including a control electrode, a first controlled electrode and a second controlled electrode; and
a diode having a first end and a second end;
wherein the second controlled electrode of the first transistor is coupled to the first end of the magnetic tunneling junction memory;
wherein the second end of the magnetic tunneling junction memory is coupled to the first controlled electrode of the second transistor and the first end of the diode;
wherein the control electrode of the first transistor is configured to be coupled to a word line;
wherein the first controlled electrode of the first transistor is configured to be coupled to a bit line;
wherein the control electrode of the second transistor is configured to be coupled to an input;
wherein the second controlled electrode of the second transistor is configured to be coupled to a first source line; and
wherein the second end of the diode is configured to be coupled to a second source line; and
flowing a first write current through the magnetic tunneling junction in a first direction to write a first logic state in the magnetic junction memory; and
flowing a second write current through the magnetic tunneling junction in a second direction opposite the first direction to write a second logic state in the magnetic junction memory.

18. The method according to claim 17,
wherein the memory cell further comprises:
a third transistor including a control electrode, a first controlled electrode and a second controlled electrode; and
a further magnetic tunneling junction memory including a first end and a second end;
wherein the second controlled electrode of the third transistor is coupled to the first end of the further magnetic tunneling junction memory;
wherein the second end of the further magnetic tunneling junction memory is coupled to the second end of the magnetic tunneling junction memory;
wherein the control electrode of the third transistor is configured to be coupled to a further word line, and
wherein the first controlled electrode of the third transistor is configured to be coupled to a further bit line.

19. The method according to claim 18, further comprising:
flowing a third write current through the further magnetic tunneling junction in a first direction to write a first logic state in the further magnetic junction memory; and
flowing a fourth write current through the further magnetic tunneling junction in a second direction opposite the first direction to write a second logic state in the further magnetic junction memory.

20. The method according to claim 19,
wherein the magnetic tunneling junction memory is configured to be in the first logic state and the further magnetic tunneling junction memory is configured to be in the second logic state to define a first logic state of the memory cell; and
wherein the magnetic tunneling junction memory is configured to be in the second logic state and the further magnetic tunneling junction memory is configured to be in the first logic state to define a second logic state of the memory cell.
